(19) United States
(12) Patent Application Publication
(10) Pub. No.: US 2025/0210914 A1
(43) Pub. Date: Jun. 26, 2025

(54) MECHANIZED CONNECTOR RECEPTACLES

(71) Applicant: Apple Inc., Cupertino, CA (US)

(72) Inventors: Nicholas A. Sims, Pleasanton, CA (US); Stephen B. Lynch, Portola Valley, CA (US); John V. Ulmen, Redwood City, CA (US); Ford E. Rylander, San Francisco, CA (US)

(73) Assignee: Apple Inc., Cupertino, CA (US)

(21) Appl. No.: 18/897,671

(22) Filed: Sep. 26, 2024

Related U.S. Application Data
(60) Provisional application No. 63/613,627, filed on Dec. 21, 2023.

(51) Int. Cl. H01R 13/629; H01R 13/62; H01R 13/66

(52) U.S. Cl. CPC H01R 13/629; H01R 13/6205; H01R 13/6683; H01R 2201/06

(57) ABSTRACT

A connector receptacle can facilitate blind mating by detecting a presence of a corresponding connector insert and in response, providing a force to pull the connector insert into the connector receptacle. Once the connector insert is inserted into the connector receptacle, the connector receptacle can provide a consistent retention force to ensure a good connection is maintained. The connector receptacle can provide breakaway protection by sensing that an ejection should occur and then in response, initiating an ejection of the connector insert.

### CROSS-REFERENCES TO RELATED APPLICATIONS

This application claims the benefit of U.S. Provisional Application No. 63/613,627, filed on Dec. 21, 2023, which is incorporated by reference.

### BACKGROUND

The number of types of electronic devices that are commercially available has increased tremendously the past few years and the rate of introduction of new devices shows no signs of abating. Devices such as tablet computers, laptop computers, all-in-one computers, desktop computers, cell phones, storage devices, wearable-computing devices, portable media players, navigation systems, monitors, adapters, and others, have become ubiquitous.

These electronic devices can receive data and power through cables that are connected to power adapters, host devices, or other data and power sources. These cables can have connector inserts at each end that can be inserted into connector receptacles in electronic devices. The connector receptacles can include contacts that can form electrical connections with corresponding contacts in the connector inserts.

These connector receptacles are often located in a rear surface or rear panel of the electronic device. For example, the cables can have a connector insert that is inserted into connector receptacle in a direction that is orthogonal to a rear of the electronic device. This configuration can make it difficult for the connector insert to be inserted by a user positioned at a front of the electronic device. It can therefore be desirable to provide a connector insert and connector receptacle that can be easily mated. This type of mating can be referred to as “blind mating” since a user is not able to see either the connector insert or the connector receptacle when a connection is being made.

These cables can be routed through locations where they might encounter inadvertent forces. For example, a cable connected to a rear or other portion of an electronic device can be inadvertently kicked by a user or passerby. It can be desirable that the cable disconnect without causing damage to the connector receptacle. That is, it is desirable that the connector receptacle provide a degree of breakaway protection.

Thus, what is needed are connector receptacles that can facilitate blind mating and provide breakaway protection.

### SUMMARY

Accordingly, embodiments of the present invention can provide connector receptacles that can facilitate blind mating and provide breakaway protection. An illustrative embodiment of the present invention can provide a connector receptacle that can facilitate blind mating by detecting a presence of a corresponding connector insert and, in response, providing a force to pull the connector insert into the connector receptacle. Once the connector insert is inserted into the connector receptacle, the connector receptacle can provide a consistent retention force to ensure that a good connection is maintained. The connector receptacle can provide breakaway protection by sensing that an ejection should occur and then in response, initiating an ejection of the connector insert. The connector receptacle can detect that an ejection should occur based on the presence of an ejection force being applied to the connector insert, either purposefully by a user during an extraction, or inadvertently by a user tripping over the cable.

These and other embodiment of the present invention can provide various drive mechanisms to provide a force to pull a corresponding connector insert into a connector receptacle, to retain the connector insert in the connector receptacle, and to eject or assist a user in an extraction of the connector insert from the connector receptacle. The connector receptacle can include a passage in a housing, the passage forming a front opening in the housing. The front opening and passage can be arranged to accept the connector insert. Drive mechanisms can be located in the passage to provide the forces for insert, retention, and ejection or extraction.

The drive mechanisms can be rollers, vacuum suction pumps and blowers, electromagnets, springs, mechanical forceps, or other drive mechanisms. For example, the drive mechanisms can be rollers that can be positioned in one or more of top, bottom, or side openings in the passage. The rollers can each rotate about axes that are orthogonal to a direction of insertion for the connector insert. The rollers can turn in a first direction to pull the connector insert into the connector receptacle. The rollers can maintain a force on the connector insert to hold the connector insert in place in the connector receptacle. The retention force on the connector insert can be applied by rollers having a rotational force. This rotational force can be the same or less than the rotational force used during an insertion. The retention force on the connector insert can be applied by rollers being in a locked position where they do not rotate. The rollers can rotate in a second direction to eject the connector insert from the connector receptacle. The rollers can have a cross-section that is circular, they can have a cam-shaped cross-section, an elliptical-shaped cross-section, or they can have another shaped cross-section. Using a cam-shaped cross-section or an elliptical shaped-cross section can essentially form a door that seals the front opening of a connector receptacle when a connector insert is not in the connector receptacle. The rollers or other drive mechanism can provide sufficient friction that they can lock a connector insert in place in the connector receptacle. This can provide a measure of security when a second end of the cable attached to the connector insert can also be locked. This can also provide a measure of security when the connector insert is a connector insert for a security or locking cable.

In these and other embodiments of the present invention, a detection of a nearby connector insert can start a vacuum pump that can lower a pressure inside the connector receptacle, thereby pulling the connector insert into the connector receptacle. A detection of a desired extraction can be detected and a positive pressure can be generated in the connector receptacle by the vacuum pump to expel the connector insert.

In another example, the drive mechanism can include an electromagnet. The electromagnet can be positioned in the connector receptacle. Current can be provided in a first direction through the electromagnet to pull the connector insert into the connector receptacle and current can be provided in a second, opposite direction through the electromagnet to eject the connector insert from the connector receptacle. Similarly, an electro-static charge can be used to generate an electric field that can help to pull a connector insert into a connector receptacle and to eject the connector insert from the connector receptacle.

The drive mechanism can include one or more springs that can be positioned in a connector receptacle. A first spring can unwind to provide a force to pull a connector insert into the passage. This first spring can further provide a retention force when the connector insert is inserted into the connector receptacle. A second spring can unwind to provide a force to eject the connector insert from the passage.

The drive mechanism can include other structures as well. For example, mechanical tweezers, forceps, or other grabbing mechanism can take hold a portion of the connector insert to pull the connector insert into the connector receptacle. Contacting surfaces of the grabbing mechanism can be adhesive, can include suction cups to improve their hold. The grabbing mechanism can inflate or extend to secure the connector insert and the deflate or retract to pull the connector insert into the connector receptacle. The grabbing mechanism can maintain a hold on the connector insert to retain the connector insert in the connector receptacle. The grabbing mechanism can inflate or extend once again to eject the connector insert from the connector receptacle.

These and other embodiments of the present invention can detect a presence of a connector insert near a connector receptacle to further facilitate blind mating. For example, a change in a magnetic field caused the connector insert can be detected by a sensor or detector in or associated with the connector receptacle. A force or stress on the rollers caused by the presence of a connector insert can be detected. A user input can start the drive mechanism. For example, a user can press a keyboard key, button, graphic icon, or other input on the electronic device or associated electronic device. This can start the drive mechanism such that it is activated as the connector insert approaches the connector receptacle. Movement of a hand behind the electronic device can be detected and can start the drive mechanism. This change in magnetic field, detected force or stress, user input, movement, or other event, can cause the drive mechanism to pull the connector insert into the connector receptacle.

These and other embodiments of the present invention can determine that an extraction is desired in various ways. For example, a force in an extraction direction can be detected, where the detected force is above a first threshold. A sharp or sudden force, for example a force provided by a user inadvertently kicking a charging cable, can be detected and an ejection can be initiated to protect the connector receptacle and its electronic device. A closing of a part of an electronic device housing the connector receptacle, such a closing of a lid on a portable device, can be detected and an ejection can be initiated. A user can type a specific key, or a button or graphic icon, to initiate an ejection. A dismount from a car charging device can be used to cause an ejection since a user is likely leaving the car at that time. A movement of an electronic device housing the connector receptacle can be detected and an ejection can be initiated. For example, a portable computing device can be picked up, dropped, or otherwise moved. An accelerometer or other sensor can detect this movement and eject a cable from the connector receptacle. The detection of an insertion of a noncompliant or faulty connector insert or cable can generate an ejection. These ejections can eject the connector insert, or it can be used to eject all cables connected to the electronic device.

These drive mechanisms can provide a tactile response to the user as the connector insert is inserted and extracted from the connector receptacle passage. Other types of feedback can be additionally included in these and other embodiments of the present invention. For example, vibrations, lights, sounds, and other types of haptic, tactile, or other feedback can be provided to a user.

These and other embodiments of the present invention can provide features to help guide a connector insert into the connector receptacle. For example, a connector receptacle can include magnets on the connector receptacle to help guide a connector insert into place in a passage of the connector receptacle. An opening of a passage in a housing to accept a connector insert can have a widening or flanged portion to help guide the connector insert into the connector receptacle.

These and other embodiments of the present invention can include various mechanisms to clean the included actuators, including drive mechanisms, rollers, and other portions of a connector receptacle. For example, a haptic engine can vibrate rollers to loosen and remove debris. The rollers can be spun at a high rate to remove dust and other debris. A vacuum can be created in the connector receptacle to pull debris into the connector receptacle where they can be gathered for cleaning. A positive pressure can be created in the connector receptacle to expel debris from the connector receptacle and its mechanisms.

Embodiments of the present invention can provide connector structures for connector receptacles that are compliant with various standards such as USB, USB Type-C, High-Definition Multimedia Interface® (HDMI), Digital Visual Interface (DVI), Ethernet, DisplayPort, Thunderbolt™, Lightning™, Joint Test Action Group (JTAG), test-access-port (TAP), Directed Automated Random Testing (DART), universal asynchronous receiver/transmitters (UARTs), clock signals, power signals, and other types of standard, non-standard, and proprietary interfaces and combinations thereof that have been developed, are being developed, or will be developed in the future.

These and other embodiments of the present invention can provide connector receptacles that can mate with conventional, rigid connector inserts, such as USB Type-C connector inserts, and the others listed above and herein. These and other embodiments of the present invention can provide other types of connector inserts. These other types of connector inserts can be mated with connector receptacles provided by embodiments of the present invention. For example, a connector insert formed of a portion of a flexible circuit board or other flexible substrate can be mated with a connector receptacle. The connector insert can be a portion of a flat flexible circuit board, a flat or round cable, such as a ribbon cable, or other conduits or grouping of flexible conductors. The flexible circuit board, cable, or other conduits can include contacts on one or more surfaces to mate with corresponding contacts in a connector receptacle.

In these and other embodiments of the present invention, contacts, ground pads, and other conductive portions of a connector receptacle can be formed by stamping, progressive stamping, forging, metal-injection molding, deep drawing, machining, micro-machining, computer-numerically controlled (CNC) machining, screw-machining, 3-D printing, clinching, or other manufacturing process. The conductive portions can be formed of stainless steel, steel, copper, copper-titanium, phosphor-bronze, brass, nickel gold, copper-nickel, silicon alloys, or other material or combination of materials. They can be plated or coated with nickel, gold, or other material.

The nonconductive portions, such as tongue moldings and other structures, can be formed using insert molding, injection molding, or other molding, 3-D printing, machining, or other manufacturing process. The nonconductive portions can be formed of silicon or silicone, polyimide, glass nylon, polycarbonate, rubber, hard rubber, plastic, nylon, liquid-crystal polymers (LCPs), ceramics, thermoplastic elastomers (TPE) or other nonconductive material or combination of materials.

Embodiments of the present invention can provide connector receptacles that can be located in various types of devices, such as tablet computers, laptop computers, desktop computers, all-in-one computers, cell phones, storage devices, wearable-computing devices, portable computing devices, portable media players, navigation systems, monitors, remotes, adapters, and other devices.

While embodiments of the present invention are well-suited to use in connector receptacles, these and other embodiments of the present invention can be utilized in connector inserts and other types of connectors as well.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 illustrates an electronic system that can be improved by the incorporation of embodiments of the present invention;

FIG. 2 illustrates an electronic device and connector receptacle according to an embodiment of the present invention;

FIG. 3 illustrates the electronic device of FIG. 2 where a connector insert has been inserted into the connector receptacle according to an embodiment of the present invention;

FIG. 4 illustrates the electronic device of FIG. 2 where a connector insert has been ejected from the connector receptacle according to an embodiment of the present invention;

FIG. 5A and FIG. 5B illustrate rollers that can be used as a drive mechanism in a connector receptacle according to an embodiment of the present invention;

FIG. 6 illustrates an electronic device and connector receptacle according to an embodiment of the present invention;

FIG. 7 illustrates the electronic device of FIG. 6 where a connector insert has been inserted into the connector receptacle according to an embodiment of the present invention;

FIG. 8 illustrates the electronic device of FIG. 6 where a connector insert has been ejected from the connector receptacle according to an embodiment of the present invention;

FIG. 9 illustrates an electronic device and connector receptacle according to an embodiment of the present invention;

FIG. 10 illustrates the electronic device of FIG. 9 where a connector insert has been inserted into the connector receptacle according to an embodiment of the present invention;

FIG. 11 illustrates the electronic device of FIG. 9 where a connector insert has been ejected from the connector receptacle according to an embodiment of the present invention;

FIG. 12 illustrates an electronic device and connector receptacle according to an embodiment of the present invention;

FIG. 13 illustrates the electronic device of FIG. 12 where a connector insert has been inserted into the connector receptacle according to an embodiment of the present invention;

FIG. 14 illustrates the electronic device of FIG. 12 where a connector insert has been ejected from the connector receptacle according to an embodiment of the present invention;

FIG. 15 illustrates an electronic device, a connector receptacle, and a corresponding connector insert according to an embodiment of the present invention; and

FIG. 16 illustrates an electronic device, a connector receptacle, and a corresponding connector insert according to an embodiment of the present invention.

### DESCRIPTION OF ILLUSTRATIVE EMBODIMENTS

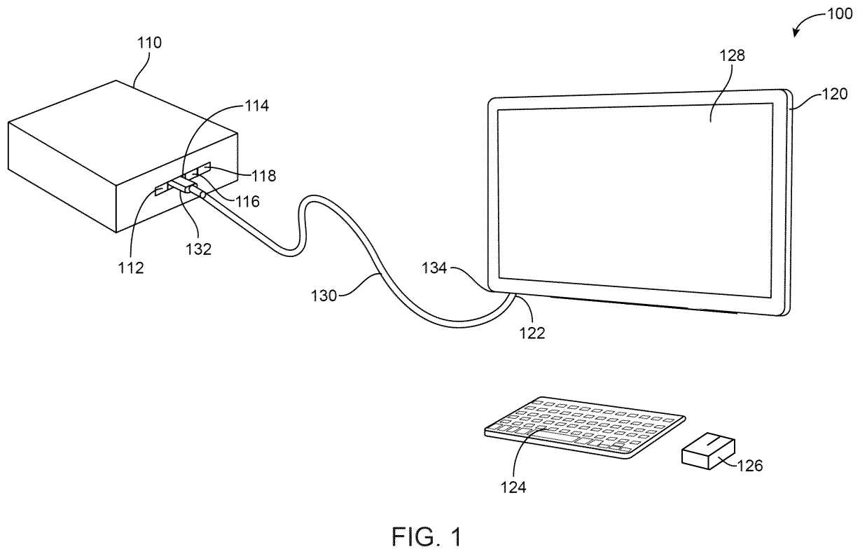

FIG. 1 illustrates an electronic system that can be improved by the incorporation of an embodiment of the present invention. This figure, as with the other included figures, is shown for illustrative purposes and does not limit either the possible embodiments of the present invention or the claims.

Electronic system 100 can include computing device 110 and electronic device 120, which is shown here as a monitor. Computing device 110 can include connector receptacle 112, connector receptacle 114, connector receptacle 116, and connector receptacle 118. Electronic device 120 and computing device 110 can communicate with keyboard 124 and mouse 126. Electronic device 120 can include screen 128. Electronic device 120 can include connector receptacle 122.

Cable 130 can convey power, data, or both between computing device 110 and electronic device 120. Cable 130 can include a connector insert 132 at a first end that can be plugged into connector receptacle 114 of computing device 110. Cable 130 can further include connector insert 134 at a second end that can be plugged into a connector receptacle of electronic device 120, for example connector receptacle 122 of electronic device 120.

In this example, electronic system 100 is shown as including computing device 110 and electronic device 120. In these and other embodiments of the present invention, electronic system 100 can include other types of devices. Also, while computing device 110 is shown as a desktop computer and electronic device 120 is shown as a desktop monitor, either or both can be other types of devices, such as laptop computers, handheld computing devices, all-in-one computers, smart phones, storage devices, wearable-computing devices, portable computing devices, portable media players, navigation systems, audio devices, remotes, adapters, and other devices.

Embodiments of the present invention can provide connector receptacles, such as connector receptacle 112 and connector receptacle 122, and connector inserts, such as connector insert 132 and connector insert 134, that are compliant with various standards such as Universal Serial Bus (USB), USB Type-C, High-Definition Multimedia Interface® (HDMI), Digital Visual Interface (DVI), Ethernet, DisplayPort, Thunderbolt™, Lightning™, Joint Test Action Group (JTAG), test-access-port (TAP), Directed Automated Random Testing (DART), universal asynchronous receiver/transmitters (UARTs), clock signals, power signals, and other types of standard, non-standard, and proprietary interfaces and combinations thereof that have been developed, are being developed, or will be developed in the future.

In this example, connector insert 134 can be inserted into connector receptacle 122. But this can be difficult since a user is likely positioned in a front of electronic device 120 where keyboard 124 and mouse 126 are positioned. Accordingly, connector receptacle 122 can include features that can facilitate the insertion of connector insert 134 into connector receptacle 122. Examples are shown in the following figures.

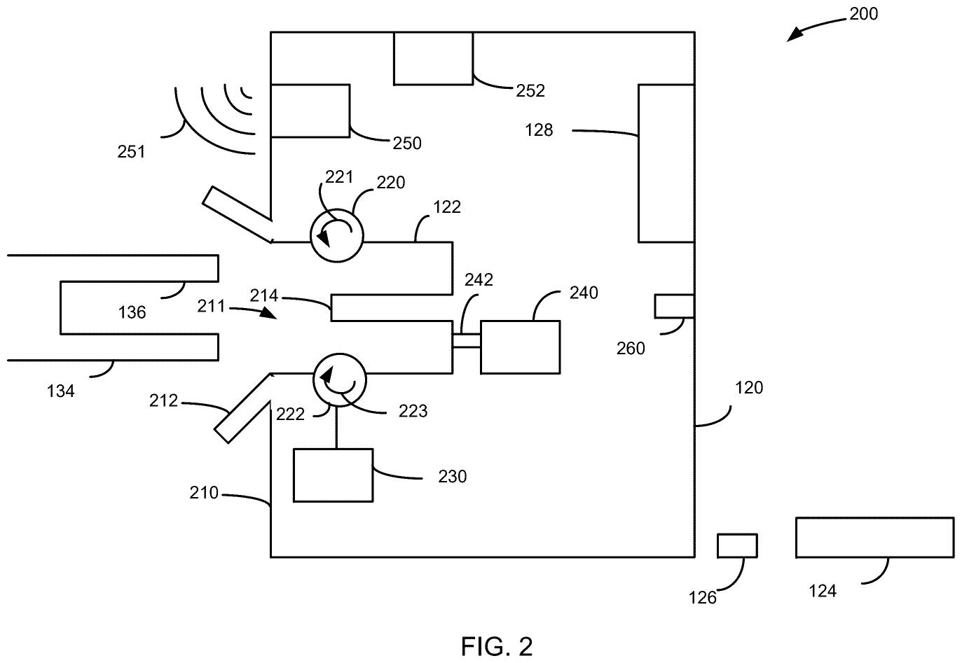

FIG. 2 illustrates an electronic device and connector receptacle according to an embodiment of the present invention. Electronic system 200 can include electronic device 120, connector insert 134, which can be connected to cable 130 (shown in FIG. 1), as well as keyboard 124 and mouse 126. Electronic device 120 can include connector receptacle 122. Connector receptacle 122 can include passage 211 in enclosure 210. Passage 211 can include tongue 214. Connector insert 134 can be inserted into passage 211 of connector receptacle 122. Opening 136 in connector insert 134 can accept tongue 214 during insertion. Contacts (not shown) on a top and bottom of tongue 214 can physically and electrically contact, and can form electrical connections with, corresponding contacts (not shown) in opening 136 of connector insert 134 when connector insert 134 is inserted into connector receptacle 122. Electronic device can further include screen 128.

These and other embodiments of the present invention can provide electronic device 120 where a user is generally expected to be positioned in front of screen 128 such that screen 128, keyboard 124, and mouse 126 are accessible. This can make it more difficult that desired to plug connector insert 134 into connector receptacle 122, since connector receptacle 122 is on the opposite side of electronic device 120 as the user. Accordingly, embodiments of the present invention can provide drive mechanisms that can provide a force on connector insert 134 to pull connector insert 134 into connector receptacle 122 during an insertion.

In these and other embodiments of the present invention, the drive mechanism can be one or more rollers. These rollers can be placed in openings in one or more of the top, bottom, or sides of passage 211. In this example, roller 220 and roller 222 can be employed. Roller 220 and roller 222 can have a surface with a high stiction, such as an adhesive, foam, or other surface. These rollers can be positioned in a top and a bottom of passage 211. When an insertion is detected, roller 220 can rotate in first direction 221 and roller 222 can rotate in second direction 223 as shown. As roller 220 and roller 222 engage connector insert 134, connector insert 134 can be pulled into passage 211 of connector receptacle 122.

Either or both roller 220 and roller 222 can be driven by motor 230. Motor 230 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This can start motor 230, which can turn roller 220 and roller 222 thereby pulling connector insert 134 into connector receptacle 122.

In these and other embodiments of the present invention, sensor 250 can be a magnetometer. One or more magnets can be included with sensor 250 to generate a magnetic field. The presence of connector insert 134 can change the magnetic field seen by sensor 250, and sensor 250 can determine that an insertion of connector insert 134 into connector receptacle 122 is desired. This can start motor 230, which can turn roller 220 and roller 222 thereby pulling connector insert 134 into connector receptacle 122.

These and other embodiments of the present invention can detect a force on either or both roller 220 or roller 222, and from that force determine that an insertion of connector insert 134 into connector receptacle 122 is desired. This detection of force can start motor 230, which can turn roller 220 and roller 222 thereby pulling connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection of force can start motor 230, which can turn roller 220 and roller 222 thereby pulling connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 120 or associated electronic device. This action by a user can start the drive mechanism such that it is activated. The user can the move connector insert 134 towards connector receptacle 122 to complete an insertion.

Engagement between connector insert 134 and connector receptacle 122 can provide a tactile response to a user as connector insert 134 is inserted into connector receptacle 122. Other types of haptic feedback can be additionally included in these and other embodiments of the present invention. For example, vibrations, lights, sounds, and other types of haptic, tactile, or other feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) to help guide connector insert 134, which can also have magnets or magnetic elements (not shown), into place in a passage of the connector receptacle. Passage 211 can have a widening or flanged tapered opening 212 to help guide connector insert 134 into connector receptacle 122.

These and other embodiments of the present invention can include various mechanisms to clean roller 220, roller 222, and other portions of connector receptacle 122. For example, a haptic engine (not shown) can vibrate roller 220 and roller 222 to loosen and remove debris. Roller 220 and roller 222 can be spun at a high rate by motor 230 to remove dust and other debris. A vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Pump 240 can be connected to passage 211 in connector receptacle 122, for example by passage 242. In these and other embodiments of the present invention, pump 240 can be part of a ventilation or cooling structure or system for electronic device 120. In these and other embodiments, pump 240 can be an air pump, fan, compressor, or other type of device. Accelerometer 252 can also be included and can be used in initiating ejection events. Accelerometer 252 can be powered down or placed in a low-power state when connector insert 134 is not plugged into connector receptacle 122.

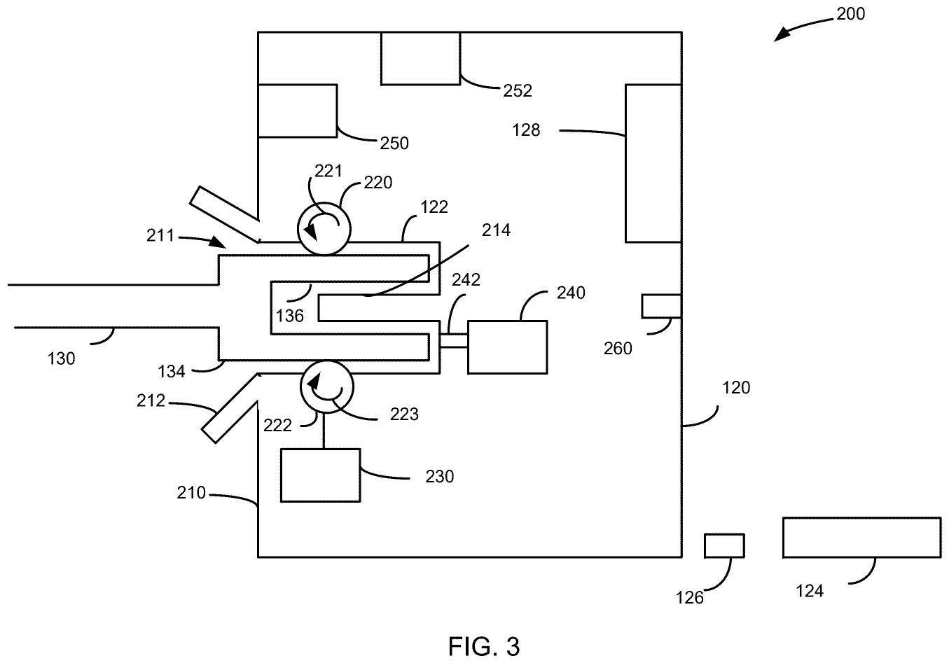

FIG. 3 illustrates the electronic device of FIG. 2 where a connector insert has been inserted into the connector receptacle according to an embodiment of the present invention. Electronic system 200 can include electronic device 120, cable 130 and connector insert 134, keyboard 124, and mouse 126. Electronic device 120 can be housed in enclosure 210, which can include tapered opening 212 and screen 128. Connector insert 134 has been inserted into passage 211 of connector receptacle 122. Tongue 214 has been inserted in opening 136 in connector insert 134. Contacts (not shown) on tongue 214 can physically and electrically connect to contacts (not shown) in opening in opening 136 of connector insert 134.

Connector receptacle 122 can provide a retention force to maintain connector insert 134 in place. For example, roller 220 can continue to try to rotate in first direction 221 and roller 222 can continue to try to rotate in second direction 223 as shown. This rotational force can be the same as or similar to a force exerted by roller 220 and roller 222 during an insertion. This rotational force can be less than the force exerted by roller 220 and roller 222 during an insertion. The retention force can instead be provided by holding or locking roller 220 and roller 222 in place and then relying on the frictional force between roller 220 and roller 222 and connector insert 134.

The ability to lock roller 220 and roller 222 in place can provide a measure of security. For example, roller 220 and roller 222 can be locked and prevented from rotating by motor 230 or other mechanism. Roller 220 and roller 222 can provide sufficient friction to connector insert 134 that it can be difficult to remove cable 130. Connector insert 134 can be a connector insert for cable 130 that is secured at a second end. Connector insert 134 can be a connector insert for a security cable. As one example, connector insert 134 can be part of a security cable that can be looped around a column of a desk or other structure that can provide a secure attachment.

While connector insert 134 is retained in connector receptacle 122, motor 230 can be powered to a lower level if the rotational force is less than the force exerted by roller 220 and roller 222 during an insertion. If the retention force is provided by holding or locking roller 220 and roller 222 in place and then relying on the frictional force between roller 220 and roller 222 and connector insert 134, motor 230 can be powered down. Sensor 250 can also be powered down. When output indicator 260 is a haptic engine or speaker, output indicator can be powered down. When output indicator 260 is a light, output indicator can be a color that can indicate that a connection between connector insert 134 and connector receptacle 122 exists. When output indicator 260 is a light and electronic device 120 is battery powered, output indicator 260 can be a color that indicates a connection between connector insert 134 and connector receptacle 122 exists and that electronic device 120 is being charged. Since connector insert 134 is inserted in connector receptacle 122, pump might not be used for cleaning, though pump 240 can be used to provide a vacuum to help keep connector insert 134 in place. Pump 240 can be connected to passage 211 through passage 242. Accelerometer 252 can be active to detect movement of electronic device 120.

In these and other embodiments of the present invention, these drive mechanisms and associated components can be used to extract or eject connector insert 134 from connector receptacle 122. An example is shown in the following figure.

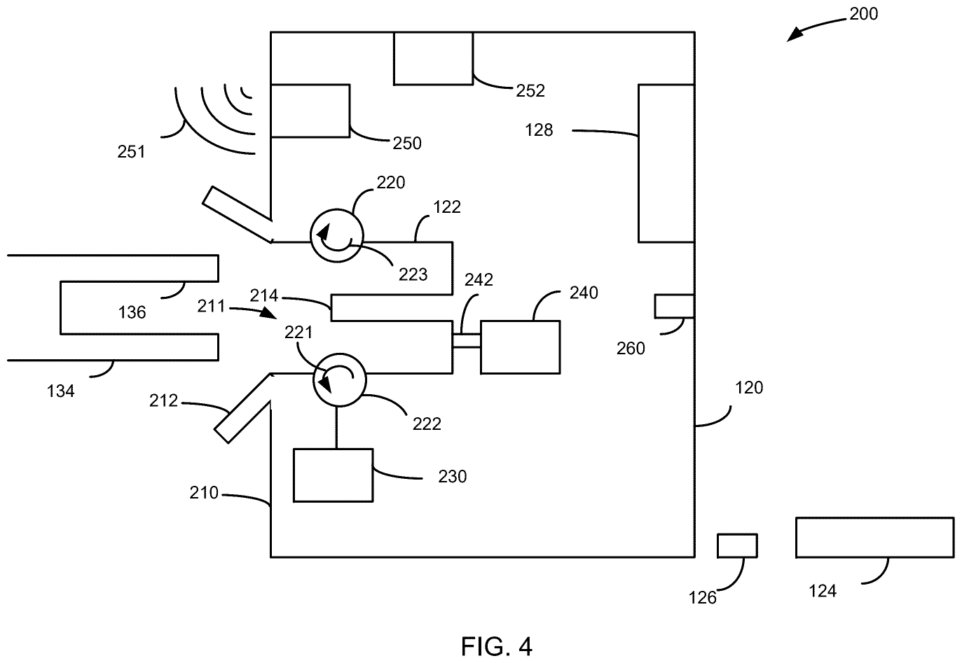

FIG. 4 illustrates the electronic device of FIG. 2 where a connector insert has been ejected or extracted from a connector receptacle according to an embodiment of the present invention. Electronic system 200 can include electronic device 120, connector insert 134, keyboard 124, and mouse 126. Electronic device 120 can be housed in enclosure 210, which can include tapered opening 212 and screen 128. Electronic device 120 has determined that an ejection event was desired. Motor 230 can turn roller 220 in the second direction 223 and roller 222 in the first direction 221. That is, motor 230 can turn roller 220 and roller 222 in opposite direction as was used when connector insert 134 was inserted into connector receptacle 122. This can eject connector insert 134 from connector receptacle 122, or it can help a user extract connector insert 134 from connector receptacle 122. Connector insert 134 is removed from passage 211 and tongue has been removed from opening 136. To further facilitate an ejection or extraction of connector insert 134, pump 240 can provide a positive pressure in passage 211 via passage 242 to provide a motivating force on connector insert 134.

Electronic device 120 can determine that an ejection event is desired in various ways. For example, motor 230 can detect that a force is attempting to rotate roller 220 in second direction 223, that the force is attempting to rotate roller 222 in first direction 221, or both. Another circuit or component (not shown) can detect that an extraction force is being applied to remove connector insert 134 from connector receptacle 122. Once this detection has been made, motor 230 can turn roller 220 in the second direction 223 and roller 222 in the first direction 221 to complete the extraction or ejection of connector insert 134 from connector receptacle 122.

The force detected by motor 230 or other component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected by motor 230 or other component and an ejection can be initiated to protect connector receptacle 122 and electronic device 120.

A movement or acceleration of electronic device 120 can be detected and can cause connector insert 134 to be ejected from connector receptacle 122. For example, electronic device 120 can be picked up, dropped, or otherwise moved. Accelerometer 252 or another sensor can detect this movement and eject connector insert 134 from connector receptacle 122. This ejection can help to prevent damage to electronic device 120. For example, a user can pick up electronic device 120 without noticing that cable 130 remains connected. This can cause the user to drop electronic device 120 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 120.

Other events can be detected and used to determine that connector insert 134 should be ejected or extracted. For example, a closing of a part of an electronic device housing the connector receptacle, such a closing of a lid (not shown) on electronic device 120 when electronic device 120 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 120 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables connected to electronic device 120.

After connector insert 134 is ejected or extracted from connector receptacle 122, sensor 250 can be activated. Sensor 250 can emit electromagnetic waves 251 that can encounter connector insert 134. When sensor 250 is a magnetometer, sensor 250 can detect a change in the magnetic field seen by sensor 250 that can indicate the presence of connector insert 134. Motor 230 can be powered down. Output indicator 260 can generate a sound, vibration, or light indicating that an ejection or extraction has occurred. Afterward, light of a specific color, or absence of light from output indicator 260, can indicate that no connection exists between connector insert 134 and connector receptacle 122.

When connector insert 134 and connector receptacle 122 are disconnected, pump 240 can be used to clean roller 220, roller 222, and other portions of connector receptacle 122. A vacuum can be created in connector receptacle 122 by pump 240 to pull debris into connector receptacle 122 where they can be gathered for cleaning. A positive pressure can be created in connector receptacle 122 by pump 240 to expel debris from connector receptacle 122 and its mechanisms. Motor 230 can spin roller 220 and roller 222 at a high rate and pump 240 can provide a vacuum or positive pressure to remove debris from connector receptacle 122. Pump 240 can be connected to passage 211 in connector receptacle 122, for example by passage 242.

Roller 220 and roller 222 can have various shapes. For example, roller 220 and roller 222 can have a roughly circular cross section as shown in the figures above. Roller 220 and roller 222 can have a cam-shaped cross-section, an elliptical-shaped cross-section, or other shaped cross-section. Such a shape can provide a door type feature that can help to keep debris out of connector receptacle 122. Such a shape can also facilitate the detection of a presence of connector insert 134. An example is shown in the following figure.

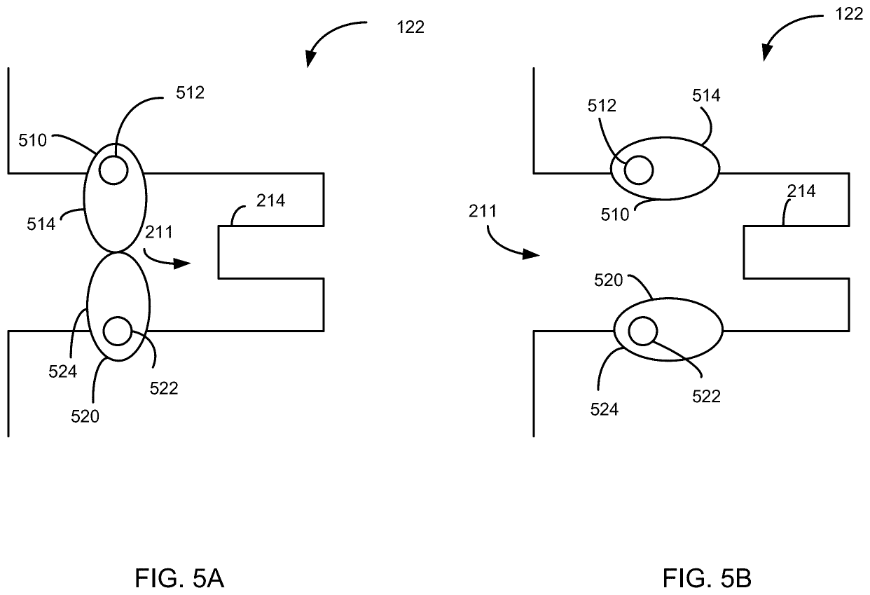

FIG. 5A and FIG. 5B illustrate rollers that can be used as part of a drive mechanism in a connector receptacle according to an embodiment of the present invention. Connector receptacle 122 can include roller 510, roller 520, and tongue 214. Roller 510 and roller 520 can be controlled and can operate in the same or similar way as roller 220 and roller 222 in the examples above.

Roller 510 can include axis or shaft 512 that is rotated by motor 230 (shown in FIG. 2.) Shaft 512 can support and be surrounded by compliant interface 514. Roller 520 can include axis or shaft 522 that is rotated by motor 230. Shaft 522 can support and be surrounded by compliant interface 524. Compliant interface 514 and compliant interface 524 can be compliant and compressible to form a pathway for connector insert 134 when connector insert 134 is inserted into connector receptacle 122. Shaft 512 and shaft 522 can be formed of metal or plastic. Compliant interface 514 and compliant interface 524 can be formed of foam, polyurethane, or other compliant material.

In FIG. 5A, when connector insert 134 is not inserted into connector receptacle 122, roller 510 and roller 520 can be in a vertical position (as drawn) with compliant interface 514 and compliant interface 524 extending towards each other. This can effectively provide a door that can block or reduce the ingress of moisture or debris into passage 211 of connector receptacle 122. Roller 510 and roller 520 can be driven by motor 230 to pull connector insert 134 into connector receptacle 122 during an insertion. Roller 510 and roller 520 can be in a similar position when connector insert 134 is retained in connector receptacle 122. Compliant interface 514 and compliant interface 524 can be in a maximum deflection, which can increase a retention force applied to connector insert 134. Roller 510 and roller 520 can be driven by motor 230 to eject connector insert 134. In FIG. 5B, roller 510 and roller 520 can be in a horizontal position (as drawn) with compliant interface 514 and compliant interface 524 extending parallel to each other. This can provide a path through passage 211, which can be used by pump 240 (shown in FIG. 2) to clear debris from connector receptacle 122. For example, pump 240 can create a positive pressure by blowing air into connector receptacle 122, thereby blowing debris out of connector receptacle 122.

In the above example, pump 240 can assist in an insertion or an ejection (or an extraction) of connector insert 134 from connector receptacle 122. In these and other embodiments of the present invention, pump 240 can be the primary drive mechanism. An example is shown in the following figure.

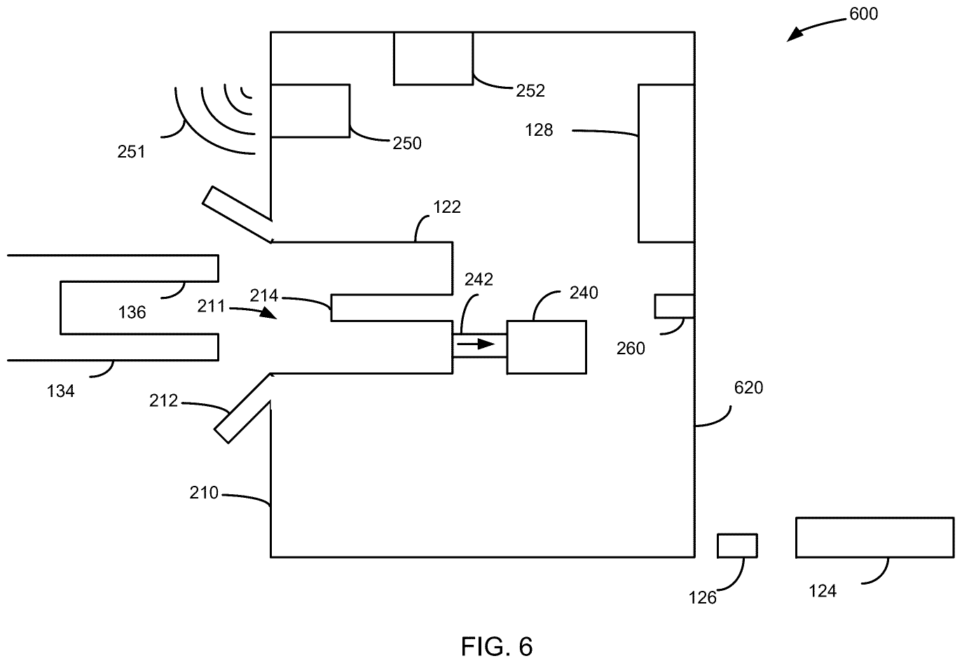

FIG. 6 illustrates an electronic device and connector receptacle according to an embodiment of the present invention. Electronic system 600 can include electronic device 620, connector insert 134, which can be connected to cable 130 (shown in FIG. 1), as well as keyboard 124 and mouse 126. Electronic device 620 can be the same as or similar to electronic device 120 (shown in FIG. 2) with the exception of the drive mechanism. Electronic device 620 can include connector receptacle 122. Connector receptacle 122 can include passage 211 in enclosure 210. Passage 211 can include tongue 214. Connector insert 134 can be inserted into passage 211 of connector receptacle 122. Opening 136 in connector insert 134 can accept tongue 214 during insertion. Contacts (not shown) on a top and bottom of tongue 214 can physically and electrically contact, and can form electrical connections with, corresponding contacts (not shown) in opening 136 of connector insert 134 when connector insert 134 is inserted into connector receptacle 122. Electronic device can further include screen 128.

As with electronic device 120, electronic device 620 can be configured where a user is generally expected to be positioned in front of screen 128 such that screen 128, keyboard 124, and mouse 126 are accessible. This can make it more difficult that desired to plug connector insert 134 into connector receptacle 122, since connector receptacle 122 is on the opposite side of electronic device 620 as the user. Accordingly, embodiments of the present invention can provide drive mechanisms that can provide a force on connector insert 134 to pull connector insert 134 into connector receptacle 122 during an insertion.

In these and other embodiments of the present invention, the drive mechanism can be a pump. The pump can provide a vacuum or positive pressure through one or more openings in one or more of the top, bottom, or sides or rear of passage 211. In this example, pump 240 can be employed. Pump can pull (to create a vacuum) or push (to create a positive pressure) air through passage 242 to connector receptacle 122. When an insertion is detected, pump 240 can pull air out of passage 211 as shown. This can help to pull connector insert 134 into passage 211 of connector receptacle 122. Pump 240 can be connected to passage 211 in connector receptacle 122, for example by passage 242.

Pump 240 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This can start pump 240, which can pull air out of passage 211 thereby pulling connector insert 134 into connector receptacle 122.

In these and other embodiments of the present invention, sensor 250 can be a magnetometer. One or more magnets (not shown) can be included with sensor 250 to generate a magnetic field. The presence of connector insert 134 can change the magnetic field seen by sensor 250, and sensor 250 can determine that an insertion of connector insert 134 into connector receptacle 122 is desired. This can start pump 240, which can pull air out of passage 211 thereby pulling connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection can start pump 240, which can pull air out of passage 211 thereby pulling connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 620 or associated electronic device. This action by a user can start the drive mechanism such that it is activated. The user can then move connector insert 134 towards connector receptacle 122 to complete the insertion.

In these and other embodiments of the present invention, pump 240 can turn on during an event detection. In these and other embodiments of the present invention, pump 240 can be part of a ventilation or cooling system for electronic device 620. In such a situation, pump 240 can occasionally be on as part of an effort to cool electronic device 620. This cooling effort can also be used to help a user plug connector insert 134 into connector receptacle 122.

Engagement between connector insert 134 and connector receptacle 122 can provide a tactile response to a user as connector insert 134 is inserted into connector receptacle 122. Other types of feedback can be additionally included in these and other embodiments of the present invention. For example, vibrations, lights, sounds, and other types of haptic, tactile, or other feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) to help guide a connector insert, which can also have magnets or magnetic elements, into place in a passage of the connector receptacle. Passage 211 can have a widening or flanged tapered opening 212 to help guide connector insert 134 into connector receptacle 122.

These and other embodiments of the present invention can include various mechanisms to clean portions of connector receptacle 122. For example, a vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Accelerometer 252 can also be included and can be used in initiating ejection events. Accelerometer 252 can be powered down or placed in a low-power state when connector insert 134 is not plugged into connector receptacle 122.

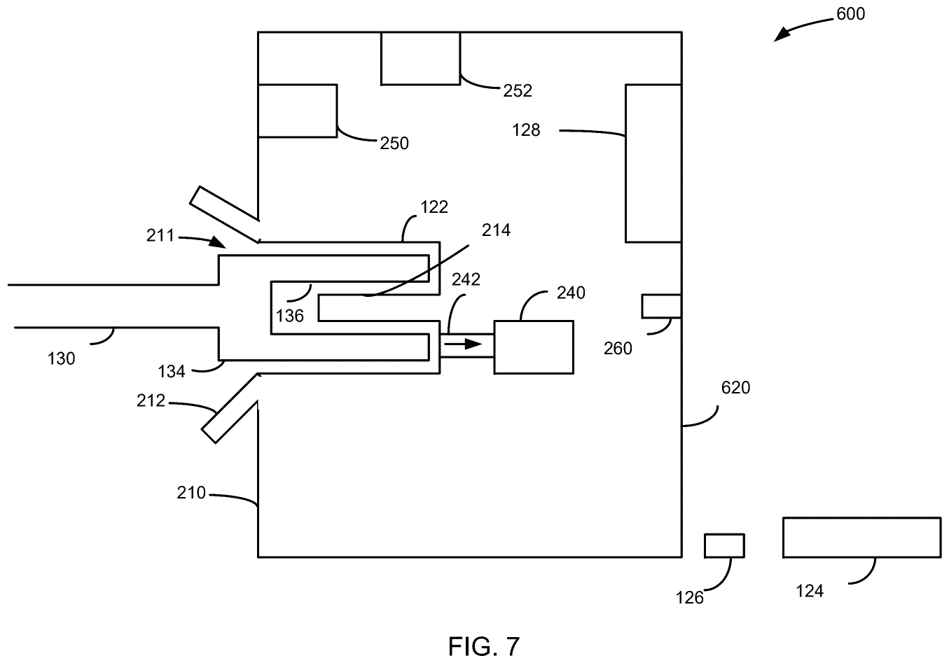

FIG. 7 illustrates the electronic device of FIG. 6 where a connector insert has been inserted into a connector receptacle according to an embodiment of the present invention. Electronic system 600 can include electronic device 620, cable 130 and connector insert 134, keyboard 124, and mouse 126. Electronic device 620 can be housed in enclosure 210, which can include tapered opening 212 and screen 128. Connector insert 134 has been inserted into passage 211 of connector receptacle 122. Tongue 214 has been inserted in opening 136 in connector insert 134. Contacts (not shown) on tongue 214 can physically and electrically connect to contacts (not shown) in opening in opening 136 of connector insert 134.

Connector receptacle 122 can provide a retention force to maintain connector insert 134 in place. For example, pump 240 can continue to provide a vacuum force in passage 211 via passage 242 to retain connector insert 134 in connector receptacle 122.

While connector insert 134 is retained in connector receptacle 122 pump 240 can be powered to a lower level or powered down, depending on the retention force needed. Sensor 250 can also be powered down. When output indicator 260 is a haptic engine or speaker, output indicator can be powered down. When output indicator 260 is a light, output indicator can be a color that can indicate that a connection between connector insert 134 and connector receptacle 122 exists. When output indicator 260 is a light and electronic device 620 is battery powered, output indicator 260 can be a color that indicates a connection between connector insert 134 and connector receptacle 122 exists and that electronic device 620 is being charged. Accelerometer 252 can be active to detect movement of electronic device 620.

In these and other embodiments of the present invention, pump 240 and associated components can be used to extract or eject connector insert 134 from connector receptacle 122. An example is shown in the following figure.

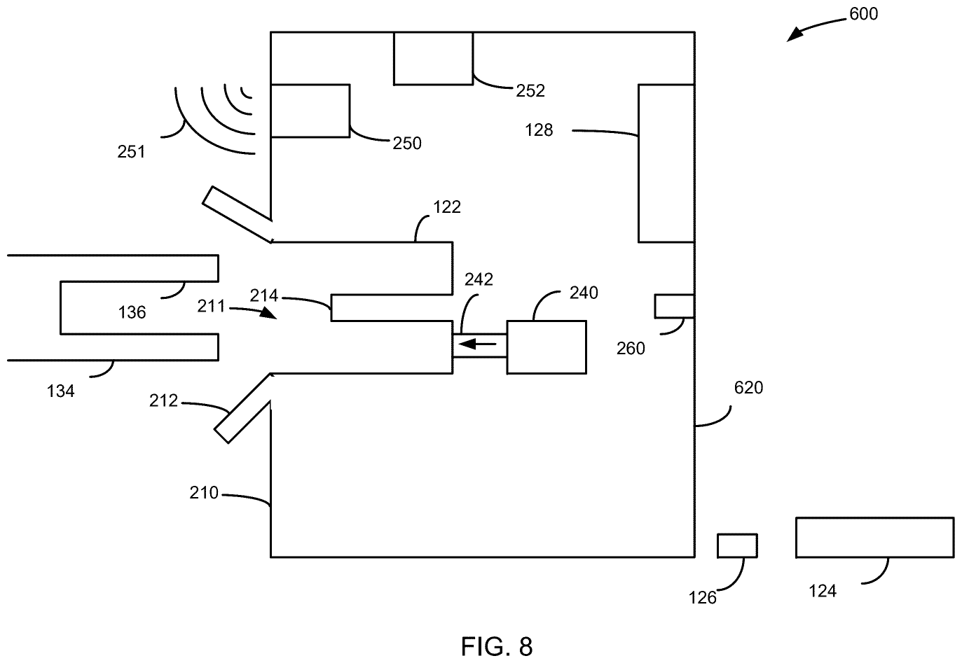

FIG. 8 illustrates the electronic device of FIG. 6 where a connector insert has been ejected or extracted from a connector receptacle according to an embodiment of the present invention. Electronic system 600 can include electronic device 620, connector insert 134, keyboard 124, and mouse 126. Electronic device 620 can be housed in enclosure 210, which can include tapered opening 212 and screen 128. Electronic device 620 has determined that an ejection event was desired. Pump 240 was activated and provided positive pressure into passage 211. This positive pressure can eject connector insert 134 from connector receptacle 122, or it can help a user extract connector insert 134 from connector receptacle 122. Contacts (not shown) on tongue 214 are disconnected from contacts (not shown) in opening 136 of connector insert 134.

Electronic device 620 can determine that an ejection event is desired in various ways. For example, a circuit or component (not shown) can detect that an extraction force is being applied to remove connector insert 134 from connector receptacle 122. Once this detection has been made, pump 240 can activate and provide a positive pressure in passage 211 thereby helping to complete the extraction or ejection of connector insert 134 from connector receptacle 122.

The force detected by the component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected and an ejection can be initiated to protect connector receptacle 122 and electronic device 620.

A movement or acceleration of electronic device 620 can be detected and can cause connector insert 134 to be ejected from connector receptacle 122. For example, electronic device 620 can be picked up, dropped, or otherwise moved. Accelerometer 252 or another sensor can detect this movement and eject connector insert 134 from connector receptacle 122. This ejection can help to prevent damage to electronic device 620. For example, a user can pick up electronic device 620 without noticing that cable 130 remains connected. This can cause the user to drop electronic device 620 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 620.

Other events can be detected and used to determine that connector insert 134 should be ejected or extracted. For example, a closing of a part of an electronic device housing the connector receptacle, such a closing of a lid (not shown) on electronic device 620 when electronic device 620 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 620 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables (not shown) connected to electronic device 620.

After connector insert 134 is ejected or extracted from connector receptacle 122, sensor 250 can be activated. Sensor 250 can emit electromagnetic waves 251 that can encounter connector insert 134. When sensor 250 is a magnetometer, sensor 250 can detect a change in the magnetic field seen by sensor 250 that can indicate the presence of connector insert 134. Output indicator 260 can generate a sound, vibration, or light indicating that an ejection or extraction has occurred. Afterward, light of a specific color, or absence of light from output indicator 260 can indicate that no connection exists between connector insert 134 and connector receptacle 122.

When connector insert 134 and connector receptacle 122 are disconnected, pump 240 can be used to clean portions of connector receptacle 122. A vacuum can be created in connector receptacle 122 by pump 240 to pull debris into connector receptacle 122 where they can be gathered for cleaning. A positive pressure can be created in connector receptacle 122 by pump 240 to expel debris from connector receptacle 122 and its mechanisms. Pump 240 can be connected to passage 211 in connector receptacle 122, for example by passage 242.

These and other embodiments of the present invention can utilize other drive mechanisms to assist in the insertion of connector insert 134 into connector receptacle 122 and the ejection or extraction of connector insert 134 from connector receptacle 122. For example, magnets, magnetic elements such as pole pieces, electromagnets, or a combination of these can be used. An example is shown in the following figure.

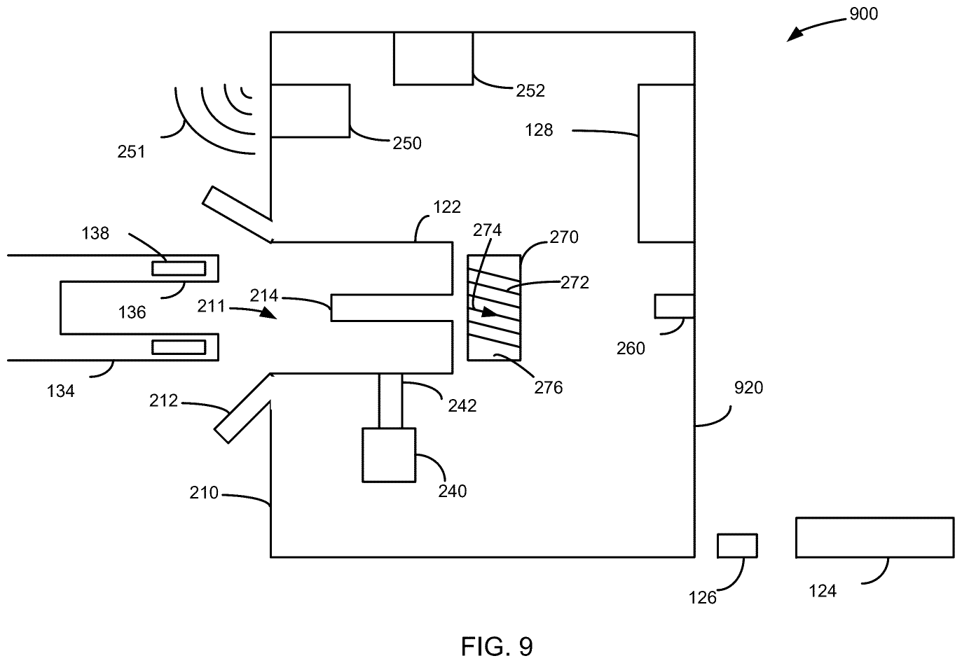

FIG. 9 illustrates an electronic device and connector receptacle according to an embodiment of the present invention. Electronic system 900 can include electronic device 920, connector insert 134, which can be connected to cable 130 (shown in FIG. 1), as well as keyboard 124 and mouse 126. Electronic device 920 can be the same as or similar to electronic device 120 (shown in FIG. 2) and electronic device 620 (shown in FIG. 6) with the exception of the drive mechanism. Electronic device 920 can include connector receptacle 122. Connector receptacle 122 can include passage 211 in enclosure 210. Passage 211 can include tongue 214. Connector insert 134 can be inserted into passage 211 of connector receptacle 122. Opening 136 in connector insert 134 can accept tongue 214 during insertion. Contacts (not shown) on a top and bottom of tongue 214 can physically and electrically contact, and can form electrical connections with, corresponding contacts (not shown) in opening 136 of connector insert 134 when connector insert 134 is inserted into connector receptacle 122. Electronic device 920 can further include screen 128.

As with electronic device 120, electronic device 920 can be configured where a user is generally expected to be positioned in front of screen 128 such that screen 128, keyboard 124, and mouse 126 are accessible. This can make it more difficult than desired to plug connector insert 134 into connector receptacle 122, since connector receptacle 122 is on the opposite side of electronic device 920 as the user. Accordingly, embodiments of the present invention can provide drive mechanisms that can provide a force on connector insert 134 to pull connector insert 134 into connector receptacle 122 during an insertion.

In these and other embodiments of the present invention, the drive mechanism can be an electromagnet. The electromagnet can provide a magnetic field that can attract or repel one or more magnets in connector insert 134. In this example, electromagnet 270 can be employed. Electromagnet 270 can include coil 272 wrapped around core 276. Current 274 can flow in a first direction through coil 272 to attract magnets 138 in connector insert 134 during an insertion and retention and in a second direction through coil 272 to repel magnets 138 in connector insert 134 during an ejection or extraction. When an insertion is detected, current can be provided through coil 272 in the first direction. This can help to pull connector insert 134 into passage 211 of connector receptacle 122.

Electromagnet 270 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This detection can start current 274 in coil 272, which can attract magnets 138 to pull connector insert 134 into connector receptacle 122.

In these and other embodiments of the present invention, sensor 250 can be a magnetometer. One or more magnets can be included with sensor 250 to generate a magnetic field. The presence of magnets 138 in connector insert 134 can change the magnetic field seen by sensor 250, and sensor 250 can determine that an insertion of connector insert 134 into connector receptacle 122 is desired. This detection can start current 274 in coil 272, which can attract magnets 138 to pull connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection can start current 274 in coil 272, which can attract magnets 138 to pull connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 920 or associated electronic device. This action by a user can start the drive mechanism such that it is activated. The user can then move connector insert 134 towards connector receptacle 122 to complete the insertion.

These and other embodiments of the present invention can include pump 240. Pump 240 can turn on during an event detection to further assist in an insertion of connector insert 134 into connector receptacle 122. In these and other embodiments of the present invention, pump 240 can be part of a ventilation system for electronic device 920. In such a situation, pump 240 can occasionally be on as part of an effort to cool electronic device 920. This cooling effort can also be used to help a user plug connector insert 134 into connector receptacle 122. Pump 240 can be connected to connector receptacle 122 via passage 242.

Engagement between connector insert 134 and connector receptacle 122 can provide a tactile response to a user as connector insert 134 is inserted into connector receptacle 122. Other types of feedback can be additionally included in these and other embodiments of the present invention. For example, vibrations, lights, sounds, and other types of haptic, tactile, or other feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) in addition to electromagnet 270 to help guide a connector insert, which can also have magnets 138 or other magnetic elements, into place in passage 211 of connector receptacle 122. Passage 211 can have a widening or flanged tapered opening 212 to help guide connector insert 134 into connector receptacle 122.

These and other embodiments of the present invention can include various mechanisms to clean portions of connector receptacle 122. For example, a vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Accelerometer 252 can also be included and can be used in initiating ejection events. Accelerometer 252 can be powered down or placed in a low-power state when connector insert 134 is not plugged into connector receptacle 122.

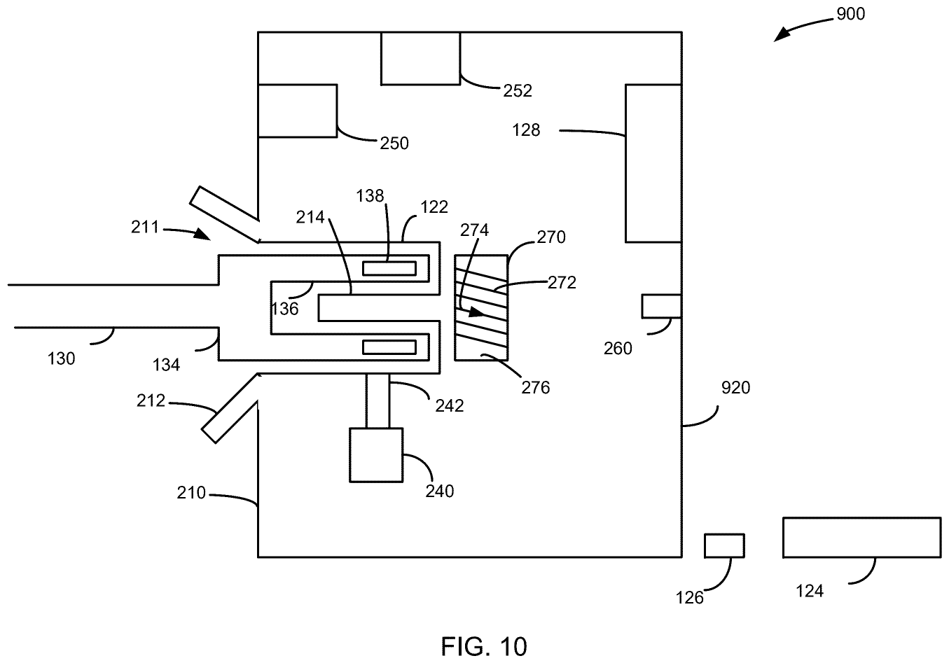

FIG. 10 illustrates the electronic device of FIG. 9 where a connector insert has been inserted into a connector receptacle according to an embodiment of the present invention. Electronic system 900 can include electronic device 920, cable 130 and connector insert 134, keyboard 124, and mouse 126. Electronic device 920 can be housed in enclosure 210, which can include tapered opening 212 and screen 128. Connector insert 134 has been inserted into passage 211 of connector receptacle 122. Tongue 214 has been inserted in opening 136 in connector insert 134. Contacts (not shown) on tongue 214 can physically and electrically connect to contacts (not shown) in opening in opening 136 of connector insert 134.

Connector receptacle 122 can provide a retention force to maintain connector insert 134 in place. For example, electromagnet 270 can continue to provide a magnetic field to attract magnets 138 to retain connector insert 134 in connector receptacle 122. Electromagnet 270 can include coil 272 around core 276. Current 274 can flow in coil to provide an attraction between electromagnet 270 and magnets 138.

Current 274 can be provided in electromagnet 270 while connector insert 134 is inserted in connector receptacle 122 to provide a measure of security. For example, electromagnet 270 can provide a locking force with magnet 138 to hold connector insert 134 in place. Electromagnet 270 can provide sufficient magnetic force with connector insert 134 and magnets 138 that it can be difficult to remove cable 130. Connector insert 134 can be a connector insert for a cable having a second end that is secured. Connector insert 134 can be a connector insert for a security cable. As an example, connector insert 134 can be a connector for a security cable that can be looped around a column of a desk or other structure that can provide a secure attachment.

While connector insert 134 is retained in connector receptacle 122 electromagnet 270 can be powered to a lower level or powered down, depending on the retention force needed. In these and other embodiments of the present invention, frictional forces can be sufficient to retain connector insert 134 in connector receptacle 122. Sensor 250 can also be powered down. When output indicator 260 is a haptic engine or speaker, output indicator 260 can be powered down. When output indicator 260 is a light, output indicator can be a color that can indicate that a connection between connector insert 134 and connector receptacle 122 exists. When output indicator 260 is a light and electronic device 920 is battery powered, output indicator 260 can be a color that indicates a connection between connector insert 134 and connector receptacle 122 exists and that electronic device 920 is being charged. Pump 240 can provide a vacuum through passage 242 to help maintain connector insert 134 in place in connector receptacle 122. Accelerometer 252 can be active to detect movement of electronic device 920.

In these and other embodiments of the present invention, electromagnet 270 and associated components can be used to extract or eject connector insert 134 from connector receptacle 122. An example is shown in the following figure.

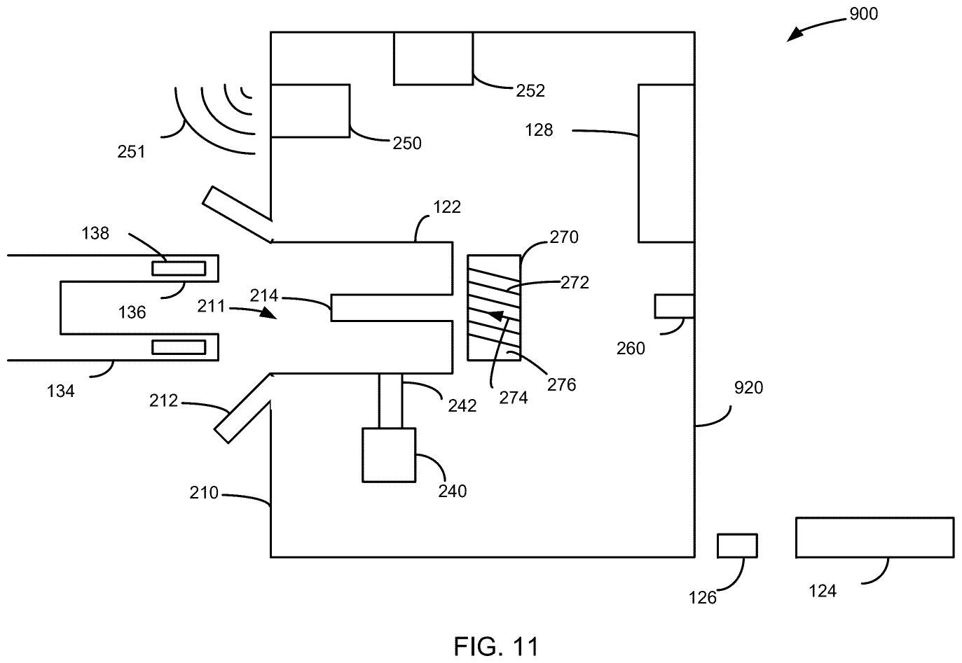

FIG. 11 illustrates the electronic device of FIG. 9 where a connector insert has been ejected or extracted from a connector receptacle according to an embodiment of the present invention. Electronic system 900 can include electronic device 920, connector insert 134, keyboard 124, and mouse 126. Electronic device 920 can be housed in enclosure 210, which can include tapered opening 212 to passage 211 and screen 128. Electronic device 920 has determined that an ejection event was desired. Current 274 in coil 272 around core 276 of electromagnet 270 was driven in the second direction to repel magnets 138 in connector insert 134. This repelling magnetic force can eject connector insert 134 from connector receptacle 122, or it can help a user extract connector insert 134 from connector receptacle 122. Contacts (not shown) on tongue 214 are disconnected from contacts (not shown) in opening 136 of connector insert 134.

Electronic device 920 can determine that an ejection event is desired in various ways. For example, a circuit or component (not shown) can detect that an extraction force is being applied to remove connector insert 134 from connector receptacle 122. Once this detection has been made, current 274 can be provided in the second direction in coil 272, thereby helping to complete the extraction or ejection of connector insert 134 from connector receptacle 122.

The force detected by the component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected and an ejection can be initiated to protect connector receptacle 122 and electronic device 920.

A movement or acceleration of electronic device 920 can be detected and can cause connector insert 134 to be ejected from connector receptacle 122. For example, electronic device 920 can be picked up, dropped, or otherwise moved. Accelerometer 252 or another sensor can detect this movement and eject connector insert 134 from connector receptacle 122. This ejection can help to prevent damage to electronic device 920. For example, a user can pick up electronic device 920 without noticing that cable 130 remains connected. This can cause the user to drop electronic device 920 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 920.

Other events can be detected and used to determine that connector insert 134 should be ejected or extracted. For example, a closing of a part of an electronic device housing the connector receptacle, such a closing of a lid (not shown) on electronic device 920 when electronic device 920 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 920 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables (not shown) connected to electronic device 920.

After connector insert 134 is ejected or extracted from connector receptacle 122, sensor 250 can be activated. Sensor 250 can emit electromagnetic waves 251 that can encounter magnets 138 in connector insert 134. When sensor 250 is a magnetometer, sensor 250 can detect a change in the magnetic field seen by sensor 250 that can indicate the presence of connector insert 134. Output indicator 260 can generate a sound, vibration, or light indicating that an ejection or extraction has occurred. Afterward, light of a specific color, or absence of light from output indicator 260 can indicate that no connection exists between connector insert 134 and connector receptacle 122.

When connector insert 134 and connector receptacle 122 are disconnected, pump 240 can be used to clean portions of connector receptacle 122. A vacuum can be created in connector receptacle 122 by pump 240 to pull debris into connector receptacle 122 where they can be gathered for cleaning. A positive pressure can be created in connector receptacle 122 by pump 240 via passage 242 to expel debris from connector receptacle 122 and its mechanisms.

These and other embodiments of the present invention can utilize other drive mechanisms to assist in the insertion of connector insert 134 into connector receptacle 122 and the ejection or extraction of connector insert 134 from connector receptacle 122. For example, one or more springs can be used. An example is shown in the following figure.

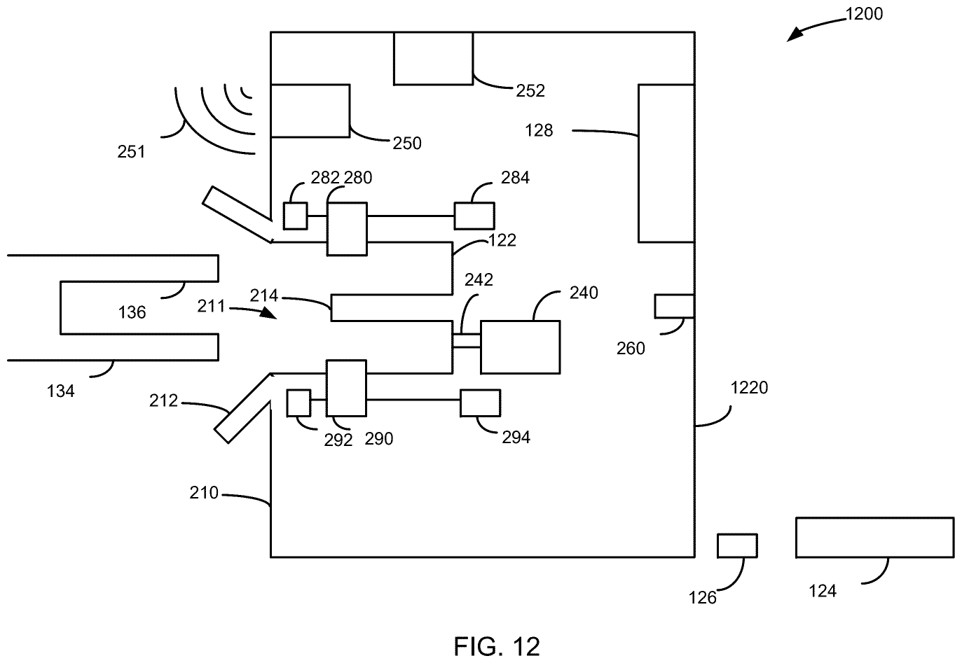

FIG. 12 illustrates an electronic device and connector receptacle according to an embodiment of the present invention. Electronic system 1200 can include electronic device 1220, connector insert 134, which can be connected to cable 130 (shown in FIG. 1), as well as keyboard 124 and mouse 126. Electronic device 1220 can be the same as or similar to electronic device 120 (shown in FIG. 2), electronic device 620 (shown in FIG. 6), and electronic device 920 (shown in FIG. 9) with the exception of the drive mechanism. Electronic device 1220 can include connector receptacle 122. Connector receptacle 122 can include passage 211 in enclosure 210. Passage 211 can include tongue 214. Connector insert 134 can be inserted into passage 211 of connector receptacle 122. Opening 136 in connector insert 134 can accept tongue 214 during insertion. Contacts (not shown) on a top and bottom of tongue 214 can physically and electrically contact, and can form electrical connections with, corresponding contacts (not shown) in opening 136 of connector insert 134 when connector insert 134 is inserted into connector receptacle 122. Electronic device 1220 can further include screen 128.

As with electronic device 120, electronic device 1220 can be configured where a user is generally expected to be positioned in front of screen 128 such that screen 128, keyboard 124, and mouse 126 are accessible. This can make it more difficult than desired to plug connector insert 134 into connector receptacle 122, since connector receptacle 122 can be on the opposite side of electronic device 1220 as the user. Accordingly, embodiments of the present invention can provide drive mechanisms that can provide a force on connector insert 134 to pull connector insert 134 into connector receptacle 122 during an insertion.

In these and other embodiments of the present invention, the drive mechanism can be contact pads driven by springs. The contact pads can contact connector insert 134. The springs can act to pull the contact pads, and thus connector insert 134 into connector receptacle 122 during an insertion. The springs can act to push the contact pads towards a front of connector receptacle 122, thereby ejecting or assisting a user in the extraction of connector insert 134 from connector receptacle 122. In this example, contact pad 280 and contact pad 290 can be employed. Contact pad 280 can be driven by spring 282 and spring 284. Contact pad 290 can be driven by spring 292 and spring 294. When an insertion is detected, spring 284 can pull contact pad 280 deeper into connector receptacle 122 and spring 294 can pull contact pad 290 deeper into connector receptacle 122. This can help to pull connector insert 134 into passage 211 of connector receptacle 122.

Spring 284 and spring 294 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, sensor 250 can be a magnetometer. One or more magnets can be included with sensor 250 to generate a magnetic field. The presence of connector insert 134 can change the magnetic field seen by sensor 250, and sensor 250 can determine that an insertion of connector insert 134 into connector receptacle 122 is desired. This detection can cause spring 284 and spring 294 to move contact pads 280 deeper into connector receptacle, which can pull connector insert 134 into connector receptacle 122.

These and other embodiments of the present invention can detect a force on contact pad 280 or contact pad 290, or both, and from that force determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 1220 or associated electronic device. This action by a user can start the drive mechanism such that it is activated. The user can then move connector insert 134 towards connector receptacle 122 to complete the insertion.

These and other embodiments of the present invention can include pump 240. Pump 240 can turn on during an event detection to further assist in an insertion of connector insert 134 into connector receptacle 122. In these and other embodiments of the present invention, pump 240 can be part of a ventilation system for electronic device 1220. In such a situation, pump 240 can occasionally be on as part of an effort to cool electronic device 1220. This cooling effort can also be used to help a user plug connector insert 134 into connector receptacle 122. Pump 240 can be connected to connector receptacle 122 via passage 242.

Engagement between connector insert 134 and connector receptacle 122 can provide a tactile response to a user as connector insert 134 is inserted into connector receptacle 122. Other types of haptic feedback can be additionally included in these and other embodiments of the present invention. For example, vibrations, lights, sounds, and other types of haptic or tactile feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) to help guide a connector insert, which can also have magnets or other magnetic elements, into place in passage 211 of connector receptacle 122. Passage 211 can have a widening or flanged tapered opening 212 to help guide connector insert 134 into connector receptacle 122.

These and other embodiments of the present invention can include various mechanisms to clean portions of connector receptacle 122. For example, a vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Accelerometer 252 can also be included and can be used in initiating ejection events. Accelerometer 252 can be powered down or placed in a low-power state when connector insert 134 is not plugged into connector receptacle 122.

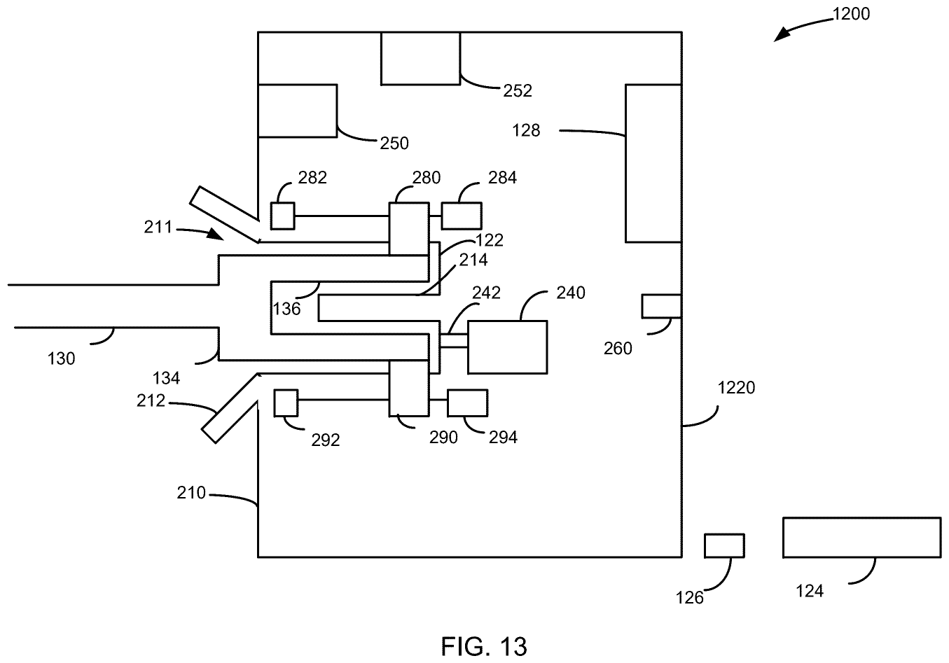

FIG. 13 illustrates the electronic device of FIG. 12 where a connector insert has been inserted into a connector receptacle according to an embodiment of the present invention. Electronic system 1200 can include electronic device 1220, cable 130 and connector insert 134, keyboard 124, and mouse 126. Electronic device 920 can be housed in enclosure 210, which can include tapered opening 212 and screen 128. Connector insert 134 has been inserted into passage 211 of connector receptacle 122. Tongue 214 has been inserted in opening 136 in connector insert 134. Contacts (not shown) on tongue 214 can physically and electrically connect to contacts (not shown) in opening in opening 136 of connector insert 134.

Connector receptacle 122 can provide a retention force to maintain connector insert 134 in place. For example, spring 284 can continue to pull contact pad 280 into connector receptacle 122 and spring 294 can continue to pull contact pad 290 into connector receptacle 122 to retain connector insert 134 in connector receptacle 122. Spring 282 and spring 292 can provide limited or no force at this point.

Contact pad 280 and contact pad 290 can be used to lock connector insert 134 in place to provide a measure of security. For example, contact pad 280 and contact pad 290 can be locked in place and prevented from moving. Contact pad 280 and contact pad 290 can provide sufficient friction to connector insert 134 that it can be difficult to remove cable 130. Connector insert 134 can be a connector insert for a cable having a second end that is secured. Connector insert 134 can be a connector insert for a security cable. As an example, connector insert 134 can be a connector insert for a security cable that can be looped around a column of a desk or other structure that can provide a secure attachment.

While connector insert 134 is retained in connector receptacle 122, frictional forces can be sufficient to retain connector insert 134 in connector receptacle 122. Sensor 250 can also be powered down. When output indicator 260 is a haptic engine or speaker, output indicator 260 can be powered down. When output indicator 260 is a light, output indicator can be a color that can indicate that a connection between connector insert 134 and connector receptacle 122 exists. When output indicator 260 is a light and electronic device 1220 is battery powered, output indicator 260 can be a color that indicates a connection between connector insert 134 and connector receptacle 122 exists and that electronic device 1220 is being charged. Pump 240 can provide a vacuum through passage 242 to help maintain connector insert 134 in place in connector receptacle 122. Accelerometer 252 can be active to detect movement of electronic device 1220.

In these and other embodiments of the present invention, contact pad 280 and contact pad 290 and associated components can be used to extract or eject connector insert 134 from connector receptacle 122. An example is shown in the following figure.

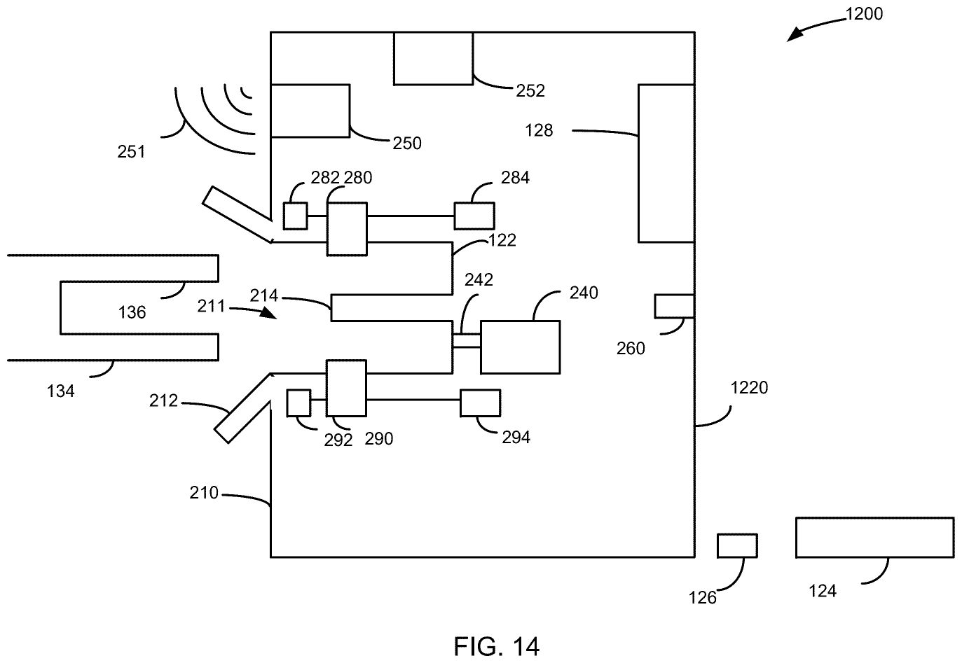

FIG. 14 illustrates the electronic device of FIG. 12 where a connector insert has been ejected or extracted from a connector receptacle according to an embodiment of the present invention. Electronic system 1200 can include electronic device 1220, connector insert 134, keyboard 124, and mouse 126. Electronic device 1220 can be housed in enclosure 210, which can include tapered opening 212 for passage 211 and screen 128. Electronic device 1220 has determined that an ejection event was desired. Spring 282 has pulled contact pad 280 towards a front of connector receptacle 122 and spring 292 has pulled contact pad 290 towards a front of connector receptacle 122. This movement can eject connector insert 134 from connector receptacle 122, or it can help a user extract connector insert 134 from connector receptacle 122. Contacts (not shown) on tongue 214 are disconnected from contacts (not shown) in opening 136 of connector insert 134. Spring 284 and spring 294 can provide little or no force at this point.

Electronic device 1220 can determine that an ejection event is desired in various ways. For example, a circuit or component (not shown) can detect that an extraction force is being applied to remove connector insert 134 from connector receptacle 122. Once this detection has been made, spring 282 can move contact pad 280 towards the front of connector receptacle 122 and spring 292 can move contact pad 290 towards the front of connector receptacle 122, thereby helping to complete the extraction or ejection of connector insert 134 from connector receptacle 122.

The force detected by the component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected by contact pad 280, contact pad 290, or other component and an ejection can be initiated to protect connector receptacle 122 and electronic device 1220.

A movement or acceleration of electronic device 1220 can be detected and can cause connector insert 134 to be ejected from connector receptacle 122. For example, electronic device 1220 can be picked up, dropped, or otherwise moved. Accelerometer 252 or another sensor can detect this movement and eject connector insert 134 from connector receptacle 122. This ejection can help to prevent damage to electronic device 1220. For example, a user can pick up electronic device 1220 without noticing that cable 130 remains connected. This can cause the user to drop electronic device 1220 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 1220.

Other events can be detected and used to determine that connector insert 134 should be ejected or extracted. For example, a closing of a part of an electronic device housing the connector receptacle, such a closing of a lid (not shown) on electronic device 1220 when electronic device 1220 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 1220 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables (not shown) connected to electronic device 1220.

After connector insert 134 is ejected or extracted from connector receptacle 122, sensor 250 can be activated. Sensor 250 can emit electromagnetic waves 251 that can encounter magnets 138 in connector insert 134. When sensor 250 is a magnetometer, sensor 250 can detect a change in the magnetic field seen by sensor 250 that can indicate the presence of connector insert 134. Output indicator 260 can generate a sound, vibration, or light indicating that an ejection or extraction has occurred. Afterward, light of a specific color, or absence of light from output indicator 260 can indicate that no connection exists between connector insert 134 and connector receptacle 122.

When connector insert 134 and connector receptacle 122 are disconnected, pump 240 can be used to clean portions of connector receptacle 122. A vacuum can be created in connector receptacle 122 by pump 240 to pull debris into connector receptacle 122 where they can be gathered for cleaning. A positive pressure can be created in connector receptacle 122 by pump 240 via passage 242 to expel debris from connector receptacle 122 and its mechanisms.

The drive mechanism can include other structures as well. For example, mechanical tweezers, forceps, or other grabbing mechanism can take hold a portion of connector insert 134 to pull connector insert 134 into connector receptacle 122. Contacting surfaces of the grabbing mechanism can be adhesive, can include suction cups to improve their hold. The grabbing mechanism can inflate or extend to secure connector insert 134 and the deflate or retract to pull connector insert 134 into connector receptacle 122. The grabbing mechanism can maintain a hold on connector insert 134 to retain connector insert in connector receptacle 122. The grabbing mechanism can inflate or extend once again to eject connector insert 134 from connector receptacle 122.

In these and other embodiments of the present invention, various features of connector insert 134 and connector receptacle 122 can provide a sufficient retention force. For example, connector insert 134 and connector receptacle 122 can be Universal Serial Bus (USB) Type-C connectors. As such, connector insert 134 can include a shield that is contacted by side ground contacts in connector receptacle 122. Tongue 214 in connector receptacle 122 can include grounded notches that can be contacted by side ground contacts in connector insert 134. These physical connections can provide a sufficient retention force, though this retention force can also be supplemented by the drive mechanisms as shown above and otherwise provided by embodiments of the present invention.

Embodiments of the present invention can provide connector structures for connector receptacles that are compliant with various standards such as USB, USB Type-C, High-Definition Multimedia Interface® (HDMI), Digital Visual Interface (DVI), Ethernet, DisplayPort, Thunderbolt™, Lightning™, Joint Test Action Group (JTAG), test-access-port (TAP), Directed Automated Random Testing (DART), universal asynchronous receiver/transmitters (UARTs), clock signals, power signals, and other types of standard, non-standard, and proprietary interfaces and combinations thereof that have been developed, are being developed, or will be developed in the future.

These and other embodiments of the present invention can provide connector receptacles that can mate with conventional, rigid connector inserts, such as USB Type-C connector inserts, and the others listed above and herein. These and other embodiments of the present invention can provide other types of connector inserts. These other types of connector inserts can be mated with connector receptacles provided by embodiments of the present invention. For example, a connector insert formed of a portion of a flexible circuit board or other flexible substrate can be mated with a connector receptacle. The connector insert can be a portion of a flat flexible circuit board, a flat or round cable, such as a ribbon cable, or other conduits or grouping of flexible conductors. The flexible circuit board, cable, or other conduits can include contacts on one or more surfaces to mate with corresponding contacts in a connector receptacle. Examples are shown in the following figures.

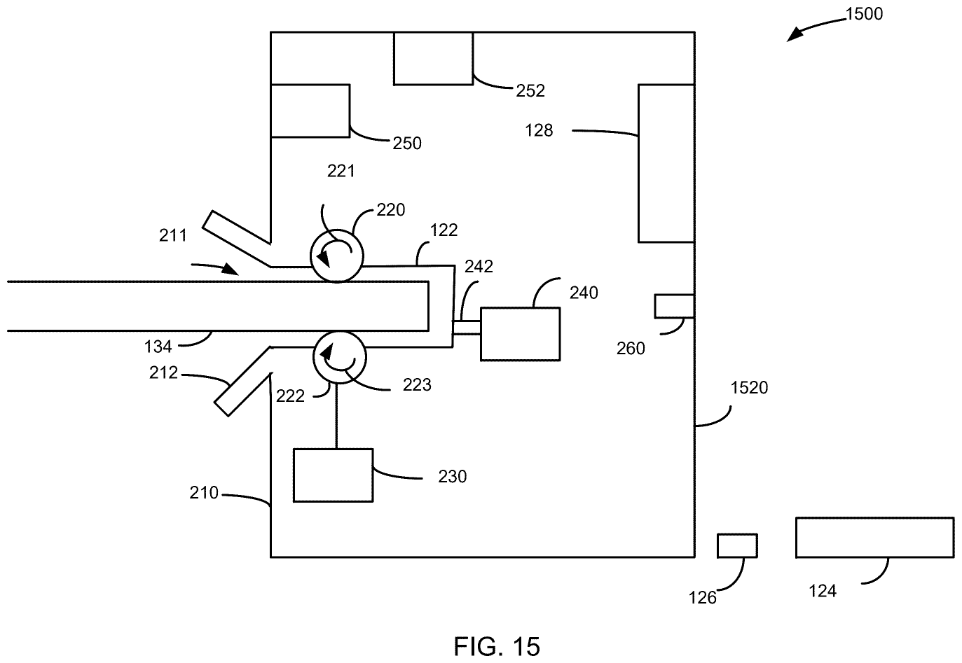

FIG. 15 illustrates an electronic device, a connector receptacle, and a corresponding connector insert according to an embodiment of the present invention. Electronic system 1500 can include electronic device 1520, connector insert 134, which can be formed of a flexible material or substrate, as well as keyboard 124 and mouse 126. Electronic device 1620 can be the same as or similar to electronic device 120 (shown in FIG. 2), electronic device 620 (shown in FIG. 6), electronic device 920 (shown in FIG. 9), and electronic device 1220 (shown in FIG. 12.) Electronic device 1520 can include connector receptacle 122. Connector receptacle 122 can include passage 211 in enclosure 210. Connector insert 134 can be inserted into passage 211 of connector receptacle 122. Contacts (not shown) in passage 211 of connector receptacle 122 can physically and electrically contact, and can form electrical connections with, corresponding contacts (not shown) on connector insert 134 when connector insert 134 is inserted into connector receptacle 122. Electronic device can further include screen 128.

In these and other embodiments of the present invention, connector inserts 134 can be various types of flexible structures or substates. For example, connector insert 134 can be a flexible circuit board. Connector insert 134 can be a substantially flat flexible circuit board that can have contacts on one or more surfaces, where the contacts physically and electrically connect to contacts in connector receptacle 122. Connector insert 134 can be a flat, circular, or other shaped cable, such as a ribbon cable. This cable can include one or more contacts on one or more surfaces that can physically and electrically connect to contacts in connector receptacle 122 when connector insert 134 is inserted into connector receptacle 122. The contacts of connector insert 134 can electrically connect to conduits in the flexible circuit board, cable, or other substrate or structure.

These and other embodiments of the present invention can provide electronic device 1520 where a user is generally expected to be positioned in front of screen 128 such that screen 128, keyboard 124, and mouse 126 are accessible. This can make it more difficult that desired to plug connector insert 134 into connector receptacle 122, since connector receptacle 122 is on the opposite side of electronic device 1520 as the user. Accordingly, embodiments of the present invention can provide drive mechanisms that can provide a force on connector insert 134 to pull connector insert 134 into connector receptacle 122 during an insertion.

As shown in FIG. 2 through FIG. 5 above, the drive mechanism for connector receptacle 122 can be one or more rollers. These rollers can be placed in openings in one or more of the top, bottom, or sides of passage 211. In this example, roller 220 and roller 222 can be employed. Roller 220 and roller 222 can have a surface with a high stiction, such as an adhesive, foam, or other surface. These rollers can be positioned in a top and a bottom of passage 211. When an insertion of connector insert 134 is detected, roller 220 can rotate in first direction 221 and roller 222 can rotate in second direction 223 as shown. As roller 220 and roller 222 engage connector insert 134, connector insert 134 can be pulled into passage 211 of connector receptacle 122. When an insertion is maintained, roller 220 can rotate in first direction 221 and roller 222 can rotate in second direction 223 to maintain a retention force on connector insert 134. During an ejection or extraction, roller 220 can rotate in second direction 223 and roller 222 can rotate in first direction 221 to force connector insert 134 from connector receptacle 122.

Either or both roller 220 and roller 222 can be driven by motor 230. Motor 230 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This can start motor 230, which can turn roller 220 and roller 222 thereby pulling connector insert 134 into connector receptacle 122. During retention, sensor 250 can be powered down, and then reactivated following an ejection or extraction.

In these and other embodiments of the present invention, sensor 250 can be a magnetometer. One or more magnets can be included with sensor 250 to generate a magnetic field. The presence of connector insert 134 can change the magnetic field seen by sensor 250, and sensor 250 can determine that an insertion of connector insert 134 into connector receptacle 122 is desired. This can start motor 230, which can turn roller 220 and roller 222 thereby pulling connector insert 134 into connector receptacle 122.

These and other embodiments of the present invention can detect a force on either or both roller 220 or roller 222, and from that force determine that an insertion of connector insert 134 into connector receptacle 122 is desired. This detection of force can start motor 230, which can turn roller 220 and roller 222 thereby pulling connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection of force can start motor 230, which can turn roller 220 and roller 222 thereby pulling connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 1520 or associated electronic device. This action by a user can start the drive mechanism such that it is activated. The user can the move connector insert 134 towards connector receptacle 122 to complete an insertion.

Engagement between connector insert 134 and connector receptacle 122 can provide a tactile response to a user as connector insert 134 is inserted into connector receptacle 122. Other types of haptic feedback can be additionally included in these and other embodiments of the present invention. For example, vibrations, lights, sounds, and other types of haptic, tactile, or other feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) to help guide connector insert 134, which can also have magnets or magnetic elements (not shown), into place in a passage of the connector receptacle. Passage 211 can have a widening or flanged tapered opening 212 to help guide connector insert 134 into connector receptacle 122.

Again, various mechanisms to clean roller 220, roller 222, and other portions of connector receptacle 122 can be included. For example, a haptic engine (not shown) can vibrate roller 220 and roller 222 to loosen and remove debris. Roller 220 and roller 222 can be spun at a high rate by motor 230 to remove dust and other debris. A vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Pump 240 can be connected to passage 211 in connector receptacle 122, for example by passage 242. In these and other embodiments of the present invention, pump 240 can be part of a ventilation or cooling structure or system for electronic device 1520. In these and other embodiments, pump 240 can be an air pump, fan, compressor, or other type of device. Accelerometer 252 can also be included and can be used in initiating ejection events. Accelerometer 252 can be powered down or placed in a low-power state when connector insert 134 is not plugged into connector receptacle 122.

Again, connector receptacle 122 can provide a retention force to maintain connector insert 134 in place. For example, roller 220 can continue to try to rotate in first direction 221 and roller 222 can continue to try to rotate in second direction 223 as shown. This rotational force can be the same as or similar to a force exerted by roller 220 and roller 222 during an insertion. This rotational force can be less than the force exerted by roller 220 and roller 222 during an insertion. The retention force can instead be provided by holding or locking roller 220 and roller 222 in place and then relying on the frictional force between roller 220 and roller 222 and connector insert 134.

The ability to lock roller 220 and roller 222 in place can provide a measure of security. For example, roller 220 and roller 222 can be locked and prevented from rotating by motor 230 or other mechanism. Roller 220 and roller 222 can provide sufficient friction to connector insert 134 that it can be difficult to remove cable 130. Connector insert 134 can be a connector insert for a cable that is attached to a power source, where the power source and the cable connection to it are secure, for example they are not readily moved or disconnected. Connector insert 134 can be a connector insert for a security cable that can be looped around a column of a desk or other structure that can provide a secure attachment.

While connector insert 134 is retained in connector receptacle 122, motor 230 can be powered to a lower level if the rotational force is less than the force exerted by roller 220 and roller 222 during an insertion. If the retention force is provided by holding or locking roller 220 and roller 222 in place and then relying on the frictional force between roller 220 and roller 222 and connector insert 134, motor 230 can be powered down. Sensor 250 can also be powered down. When output indicator 260 is a haptic engine or speaker, output indicator can be powered down. When output indicator 260 is a light, output indicator can be a color that can indicate that a connection between connector insert 134 and connector receptacle 122 exists. When output indicator 260 is a light and electronic device 1520 is battery powered, output indicator 260 can be a color that indicates a connection between connector insert 134 and connector receptacle 122 exists and that electronic device 1520 is being charged. Since connector insert 134 is inserted in connector receptacle 122, pump might not be used for cleaning, though pump 240 can be used to provide a vacuum to help keep connector insert 134 in place. Pump 240 can be connected to passage 211 through passage 242.

Electronic device 1520 can determine that an ejection event is desired in various ways. For example, motor 230 can detect that a force is attempting to rotate roller 220 in second direction 223, that the force is attempting to rotate roller 222 in first direction 221, or both. Another circuit or component (not shown) can detect that an extraction force is being applied to remove connector insert 134 from connector receptacle 122. Once this detection has been made, motor 230 can turn roller 220 in the second direction 223 and roller 222 in the first direction 221 to complete the extraction or ejection of connector insert 134 from connector receptacle 122.

The force detected by motor 230 or other component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected by motor 230 or other component and an ejection can be initiated to protect connector receptacle 122 and electronic device 1520.

A movement or acceleration of electronic device 1520 can be detected and can cause connector insert 134 to be ejected from connector receptacle 122. For example, electronic device 1520 can be picked up, dropped, or otherwise moved. Accelerometer 252 or another sensor can detect this movement and eject connector insert 134 from connector receptacle 122. This ejection can help to prevent damage to electronic device 1520. For example, a user can pick up electronic device 1520 without noticing that cable 130 remains connected. This can cause the user to drop electronic device 1520 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 1520.

Other events can be detected and used to determine that connector insert 134 should be ejected or extracted. For example, a closing of a part of an electronic device housing the connector receptacle, such a closing of a lid (not shown) on electronic device 1520 when electronic device 1520 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 1520 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables connected to electronic device 1520. To further facilitate an ejection or extraction of connector insert 134, pump 240 can provide a positive pressure in passage 211 via passage 242 to provide a motivating force on connector insert 134.

After connector insert 134 is ejected or extracted from connector receptacle 122, sensor 250 can be activated. Sensor 250 can emit electromagnetic waves 251 that can encounter connector insert 134. When sensor 250 is a magnetometer, sensor 250 can detect a change in the magnetic field seen by sensor 250 that can indicate the presence of connector insert 134. Motor 230 can be powered down. Output indicator 260 can generate a sound, vibration, or light indicating that an ejection or extraction has occurred. Afterward, light of a specific color, or absence of light from output indicator 260, can indicate that no connection exists between connector insert 134 and connector receptacle 122.

When connector insert 134 and connector receptacle 122 are disconnected, pump 240 can be used to clean roller 220, roller 222, and other portions of connector receptacle 122. A vacuum can be created in connector receptacle 122 by pump 240 to pull debris into connector receptacle 122 where they can be gathered for cleaning. A positive pressure can be created in connector receptacle 122 by pump 240 to expel debris from connector receptacle 122 and its mechanisms. Motor 230 can spin roller 220 and roller 222 at a high rate and pump 240 can provide a vacuum or positive pressure to remove debris from connector receptacle 122. Pump 240 can be connected to passage 211 in connector receptacle 122, for example by passage 242.

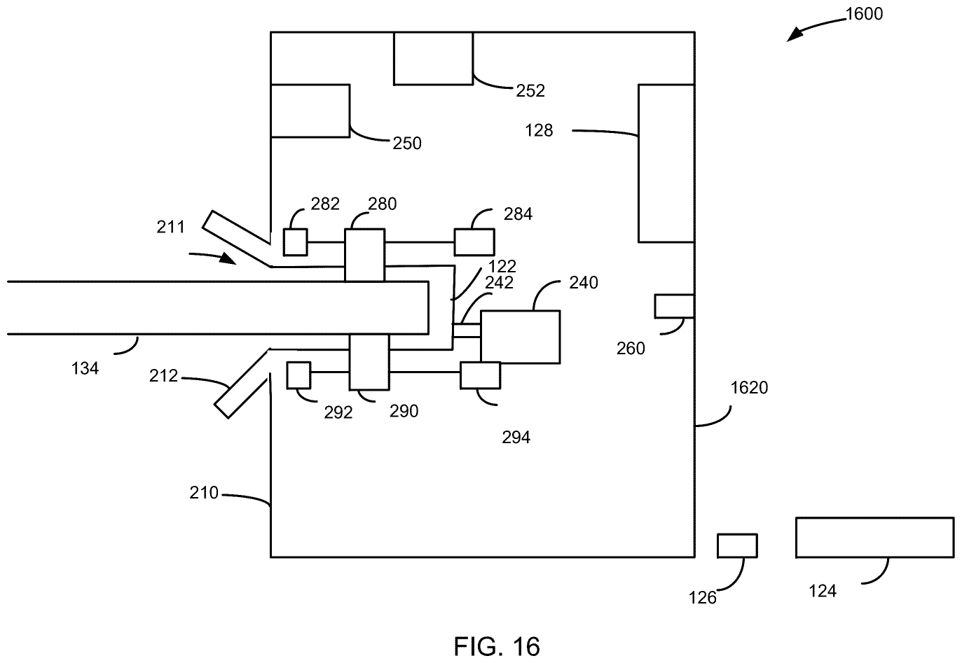

FIG. 16 illustrates an electronic device, a connector receptacle, and a corresponding connector insert according to an embodiment of the present invention. Electronic system 1600 can include electronic device 1620, connector insert 134, which can be connected to cable 130 (shown in FIG. 1), as well as keyboard 124 and mouse 126. Electronic device 1620 can be the same as or similar to electronic device 120 (shown in FIG. 2), electronic device 620 (shown in FIG. 6), and electronic device 920 (shown in FIG. 9.) Electronic device 1620 can include connector receptacle 122. Connector insert 134 can be inserted into passage 211 of connector receptacle 122. Contacts (not shown) in passage 211 of connector receptacle 122 can physically and electrically contact, and can form electrical connections with, corresponding contacts (not shown) on connector insert 134 when connector insert 134 is inserted into connector receptacle 122. Electronic device can further include screen 128.

In these and other embodiments of the present invention, connector inserts 134 can be various types of flexible structures or substates. For example, connector insert 134 can be a flexible circuit board. Connector insert 134 can be a substantially flat flexible circuit board that can have contacts on one or more surfaces, where the contacts physically and electrically connect to contacts in connector receptacle 122. Connector insert 134 can be a flat, circular, or other shaped cable, such as a ribbon cable. This cable can include one or more contacts on one or more surfaces that can physically and electrically connect to contacts in connector receptacle 122 when connector insert 134 is inserted into connector receptacle 122. The contacts of connector insert 134 can electrically connect to conduits in the flexible circuit board, cable, or other substrate or structure.

As with electronic device 120, electronic device 1620 can be configured where a user is generally expected to be positioned in front of screen 128 such that screen 128, keyboard 124, and mouse 126 are accessible. This can make it more difficult than desired to plug connector insert 134 into connector receptacle 122, since connector receptacle 122 can be on the opposite side of electronic device 1620 as the user. Accordingly, embodiments of the present invention can provide drive mechanisms that can provide a force on connector insert 134 to pull connector insert 134 into connector receptacle 122 during an insertion.

As shown in FIG. 12 through FIG. 14, the drive mechanism can be contact pads driven by springs. The contact pads can contact connector insert 134. The springs can act to pull the contact pads, and thus connector insert 134 into connector receptacle 122 during an insertion. The springs can act to push the contact pads towards a front of connector receptacle 122, thereby ejecting or assisting a user in the extraction of connector insert 134 from connector receptacle 122. In this example, contact pad 280 and contact pad 290 can be employed. Contact pad 280 can be driven by spring 282 and spring 284. Contact pad 290 can be driven by spring 292 and spring 294. When an insertion is detected, spring 284 can pull contact pad 280 deeper into connector receptacle 122 and spring 294 can pull contact pad 290 deeper into connector receptacle 122. This can help to pull connector insert 134 into passage 211 of connector receptacle 122. When an insertion is maintained, spring 284 can continue to provide a force on contact pad 280 and spring 294 can continue to provide a force on contact pad 290. This can maintain a retention of connector insert 134 in connector receptacle 122. During an ejection or extraction, spring 282 can pull contact pad 280 and spring 292 can pull contact pad 290 towards the opening in connector receptacle 122, thereby ejecting or helping to extract connector insert 134 from connector receptacle 122.

Spring 284 and spring 294 can be activated by a detection of connector insert 134 or other event. In these and other embodiments of the present invention, a presence of connector insert 134 can be detected by sensor 250. Sensor 250 can emit electromagnetic waves 251 that can encounter connector insert 134. Sensor 250 can detect a change in the impedance seen by electromagnetic waves 251 caused by connector insert 134 and can determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, sensor 250 can be a magnetometer. One or more magnets can be included with sensor 250 to generate a magnetic field. The presence of connector insert 134 can change the magnetic field seen by sensor 250, and sensor 250 can determine that an insertion of connector insert 134 into connector receptacle 122 is desired. This detection can cause spring 284 and spring 294 to move contact pads 280 deeper into connector receptacle, which can pull connector insert 134 into connector receptacle 122.

These and other embodiments of the present invention can detect a force on contact pad 280 or contact pad 290, or both, and from that force determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, sensor 250 can detect movement of a hand, connector insert 134, or both, near connector receptacle 122. From the detection of this movement, sensor 250 can determine that an insertion of connector insert 134 into connector receptacle 122 is desired. This detection can cause spring 284 and spring 294 to move contact pads 280 deeper into connector receptacle, which can pull connector insert 134 into connector receptacle 122.

In these and other embodiments of the present invention, a user input can start the drive mechanism. For example, a user can press a key on keyboard 124, can select a graphic icon on screen 128 using touch or mouse 126, or can generate other input on electronic device 1620 or associated electronic device. This action by a user can start the drive mechanism such that it is activated. The user can then move connector insert 134 towards connector receptacle 122 to complete the insertion.

These and other embodiments of the present invention can include pump 240. Pump 240 can turn on during an event detection to further assist in an insertion of connector insert 134 into connector receptacle 122. In these and other embodiments of the present invention, pump 240 can be part of a ventilation system for electronic device 1620. In such a situation, pump 240 can occasionally be on as part of an effort to cool electronic device 1620. This cooling effort can also be used to help a user plug connector insert 134 into connector receptacle 122. Pump 240 can be connected to connector receptacle 122 via passage 242.

Engagement between connector insert 134 and connector receptacle 122 can provide a tactile response to a user as connector insert 134 is inserted into connector receptacle 122. Other types of haptic feedback can be additionally included in these and other embodiments of the present invention. For example, vibrations, lights, sounds, and other types of haptic or tactile feedback can be provided to a user via output indicator 260. Output indicator 260 can be a haptic engine, a light, a speaker or other device that can be activated by sensor 250 or other circuit. For example, output device can be activated by sensor 250 detecting connector insert 134, by the insertion of connector insert 134 in connector receptacle 122, or by other event.

These and other embodiments of the present invention can provide features to help guide a connector insert into the connector receptacle. For example, connector receptacle 122 can include magnets or magnetic elements (not shown) to help guide a connector insert, which can also have magnets or other magnetic elements, into place in passage 211 of connector receptacle 122. Passage 211 can have a widening or flanged tapered opening 212 to help guide connector insert 134 into connector receptacle 122.

Again, various mechanisms to clean portions of connector receptacle 122 can be included. For example, a vacuum can be created in connector receptacle 122 by pump 240 to pull debris into the connector receptacle where they can be gathered for cleaning. A positive pressure can be created in connector receptacle 122 by pump 240 to expel debris from connector receptacle 122 and its mechanisms. Accelerometer 252 can also be included and can be used in initiating ejection events. Accelerometer 252 can be powered down or placed in a low-power state when connector insert 134 is not plugged into connector receptacle 122.

Again, connector receptacle 122 can provide a retention force to maintain connector insert 134 in place. For example, spring 284 can continue to pull contact pad 280 into connector receptacle 122 and spring 294 can continue to pull contact pad 290 into connector receptacle 122 to retain connector insert 134 in connector receptacle 122. Spring 282 and spring 292 can provide limited or no force at this point.

Contact pad 280 and contact pad 290 can be used to lock connector insert 134 in place to provide a measure of security. For example, contact pad 280 and contact pad 290 can be locked in place and prevented from moving. Contact pad 280 and contact pad 290 can provide sufficient friction to connector insert 134 that it can be difficult to remove cable 130. Connector insert 134 can be a connector insert for a cable having a second end that is secured. Connector insert 134 can be a connector insert for a security cable. As an example, connector insert can be a connector insert for a security cable that can be looped around a column of a desk or other structure that can provide a secure attachment.

While connector insert 134 is retained in connector receptacle 122, frictional forces can be sufficient to retain connector insert 134 in connector receptacle 122. Sensor 250 can also be powered down. When output indicator 260 is a haptic engine or speaker, output indicator 260 can be powered down. When output indicator 260 is a light, output indicator can be a color that can indicate that a connection between connector insert 134 and connector receptacle 122 exists. When output indicator 260 is a light and electronic device 1620 is battery powered, output indicator 260 can be a color that indicates a connection between connector insert 134 and connector receptacle 122 exists and that electronic device 1620 is being charged. Pump 240 can provide a vacuum through passage 242 to help maintain connector insert 134 in place in connector receptacle 122. Accelerometer 252 can be active to detect movement of electronic device 1620.

Electronic device 1620 can determine that an ejection event is desired in various ways. For example, a circuit or component (not shown) can detect that an extraction force is being applied to remove connector insert 134 from connector receptacle 122. Once this detection has been made, spring 282 can move contact pad 280 towards the front of connector receptacle 122 and spring 292 can move contact pad 290 towards the front of connector receptacle 122, thereby helping to complete the extraction or ejection of connector insert 134 from connector receptacle 122.

The force detected by the component can be required to be above a first threshold in order to prevent or reduce a number of unintended ejections. This threshold can be set high enough to reduce unintended ejections, but low enough to enable a user to extract connector insert 134 even when the user might not secure a grip on cable 130 (shown in FIG. 1) or connector insert 134 due to their location. A sharp or sudden force, for example a force provided by a user inadvertently kicking cable 130, can be detected by contact pad 280, contact pad 290, or other component and an ejection can be initiated to protect connector receptacle 122 and electronic device 1620.

A movement or acceleration of electronic device 1620 can be detected and can cause connector insert 134 to be ejected from connector receptacle 122. For example, electronic device 1620 can be picked up, dropped, or otherwise moved. Accelerometer 252 or another sensor can detect this movement and eject connector insert 134 from connector receptacle 122. This ejection can help to prevent damage to electronic device 1620. For example, a user can pick up electronic device 1620 without noticing that cable 130 remains connected. This can cause the user to drop electronic device 1620 or can otherwise cause damage to connector receptacle 122. To prevent this, accelerometer 252 can detect movement or acceleration and can cause the ejection of connector insert 134. This detected movement or acceleration can also or instead cause the ejection of all cables (not shown) connected to electronic device 1620.

Other events can be detected and used to determine that connector insert 134 should be ejected or extracted. For example, a closing of a part of an electronic device housing the connector receptacle, such a closing of a lid (not shown) on electronic device 1620 when electronic device 1620 is a portable device, can be detected and an ejection can be initiated. A user can type a specific key on keyboard 124, a button or graphic icon on screen 128 can be selected with mouse 126, a specific phrase can be spoken by a user, or other user input can initiate an ejection. A dismount of electronic device 1620 from a car charging device (not shown) can be used to cause an ejection since a user is likely leaving a car (not shown) at that time. The detection of an insertion of a noncompliant or faulty connector insert or cable (not shown) can generate an ejection. These detections can cause the ejection of connector insert 134, or they can cause the ejection of all cables (not shown) connected to electronic device 1620.

After connector insert 134 is ejected or extracted from connector receptacle 122, sensor 250 can be activated. Sensor 250 can emit electromagnetic waves 251 that can encounter magnets 138 in connector insert 134. When sensor 250 is a magnetometer, sensor 250 can detect a change in the magnetic field seen by sensor 250 that can indicate the presence of connector insert 134. Output indicator 260 can generate a sound, vibration, or light indicating that an ejection or extraction has occurred. Afterward, light of a specific color, or absence of light from output indicator 260 can indicate that no connection exists between connector insert 134 and connector receptacle 122.

When connector insert 134 and connector receptacle 122 are disconnected, pump 240 can be used to clean portions of connector receptacle 122. A vacuum can be created in connector receptacle 122 by pump 240 to pull debris into connector receptacle 122 where they can be gathered for cleaning. A positive pressure can be created in connector receptacle 122 by pump 240 via passage 242 to expel debris from connector receptacle 122 and its mechanisms.

The drive mechanism can include other structures as well. For example, mechanical tweezers, forceps, or other grabbing mechanism can take hold a portion of connector insert 134 to pull connector insert 134 into connector receptacle 122. Contacting surfaces of the grabbing mechanism can be adhesive, can include suction cups to improve their hold. The grabbing mechanism can inflate or extend to secure connector insert 134 and the deflate or retract to pull connector insert 134 into connector receptacle 122. The grabbing mechanism can maintain a hold on connector insert 134 to retain connector insert in connector receptacle 122. The grabbing mechanism can inflate or extend once again to eject connector insert 134 from connector receptacle 122.

In these and other embodiments of the present invention, various features of connector insert 134 and connector receptacle 122 can provide a sufficient retention force. For example, connector insert 134 and connector receptacle 122 can be Universal Serial Bus (USB) Type-C connectors. As such, connector insert 134 can include a shield that is contacted by side ground contacts in connector receptacle 122. Tongue 214 in connector receptacle 122 can include grounded notches that can be contacted by side ground contacts in connector insert 134. These physical connections can provide a sufficient retention force, though this retention force can also be supplemented by the drive mechanisms as shown above and otherwise provided by embodiments of the present invention.

In these and other embodiments of the present invention, contacts, ground pads, and other conductive portions of a connector receptacle can be formed by stamping, progressive stamping, forging, metal-injection molding, deep drawing, machining, micro-machining, computer-numerically controlled (CNC) machining, screw-machining, 3-D printing, clinching, or other manufacturing process. The conductive portions can be formed of stainless steel, steel, copper, copper-titanium, phosphor-bronze, brass, nickel gold, copper-nickel, silicon alloys, or other material or combination of materials. They can be plated or coated with nickel, gold, or other material.

The nonconductive portions, such as tongue moldings, ribs, and other structures, can be formed using insert molding, injection molding, or other molding, 3-D printing, machining, or other manufacturing process. The nonconductive portions can be formed of silicon or silicone, polyimide, glass nylon, polycarbonate, rubber, hard rubber, plastic, nylon, liquid-crystal polymers (LCPs), ceramics, thermoplastic elastomers (TPE) or other nonconductive material or combination of materials.

Embodiments of the present invention can provide connector receptacles that can be located in various types of devices, such as tablet computers, laptop computers, desktop computers, all-in-one computers, cell phones, storage devices, wearable-computing devices, portable computing devices, portable media players, navigation systems, monitors, remotes, adapters, and other devices.

While embodiments of the present invention are well-suited to use in connector receptacles, these and other embodiments of the present invention can be utilized in connector inserts and other types of connectors as well. Reference numbers are used here in a consistent manner among the various figures.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A connector receptacle comprising:
a housing;
a passage in the housing, the passage defining a front opening in the housing, the front opening and the passage configured to accept a corresponding connector insert;
a first plurality of contacts located in the passage of the housing;
a detector to detect a presence of the connector insert; and
a drive mechanism coupled to the detector to provide a force to pull the connector insert into the passage in response to detecting the presence of the connector insert.

2. The connector receptacle of claim 1 wherein the drive mechanism is further configured to:
provide a retention force when the connector insert is positioned in the connector receptacle.

3. The connector receptacle of claim 2 wherein the connector receptacle is further configured to detect an extraction force; and
wherein the drive mechanism is further configured to eject the connector insert in response to detecting the extraction force.

4. The connector receptacle of claim 3 wherein the drive mechanism includes a first roller, the first roller accessible in a top opening in the passage in the housing.

5. The connector receptacle of claim 4 wherein the first roller rotates about a first axis to engage a portion of the connector insert, wherein the first axis is orthogonal to a direction of insertion for the connector insert.

6. The connector receptacle of claim 5 wherein the drive mechanism further comprises a second roller, the second roller accessible in a bottom opening in the passage in the housing, wherein the second roller rotates about a second axis to engage a portion of the connector insert, wherein the second axis is parallel to the first axis.

7. The connector receptacle of claim 6 wherein the first roller and the second roller engage a connector insert during an insertion, retention, and extraction, and the first plurality of contacts in the connector receptacle engage a second plurality of contacts in the connector insert when the connector insert is inserted in the connector receptacle.

8. A connector receptacle comprising:
a housing;
a passage in the housing, the passage defining a front opening in the housing, the front opening and the passage configured to accept a corresponding connector insert;
a first plurality of contacts located in the passage of the housing; and
a detector to detect a presence of the connector insert, where the presence of the connector insert is detected in an area that is larger than the front opening of the housing; and
a drive mechanism coupled to the detector to pull the connector insert into the passage in response to detecting the presence of the connector insert, to retain the connector insert after the connector is inserted into the connector receptacle, and to eject the connector insert from the connector receptacle.

9. The connector receptacle of claim 8 wherein the drive mechanism provides a retention force when the connector insert is in the passage of the connector receptacle.

10. The connector receptacle of claim 9 wherein the drive mechanism provides an extraction force to eject the connector insert when an extraction force on the connector insert is detected by the connector receptacle.

11. The connector receptacle of claim 10 further comprising a haptic feedback component to provide a response to a user when the connector insert is pulled into the passage.

12. The connector receptacle of claim 11 wherein the response to the user comprises tactile feedback.

13. The connector receptacle of claim 8 wherein the connector insert is formed of a flexible circuit board, the flexible circuit board having contacts on either or both sides.

14. The connector receptacle of claim 8 wherein the drive mechanism can lock the connector insert in place when the connector insert is retained in the connector receptacle.

15. A connector receptacle comprising:
a housing;
a passage in the housing, the passage defining a front opening in the housing, the front opening and the passage configured to accept a corresponding connector insert;
a first plurality of contacts located in the passage of the housing;
a first detector to detect an extraction force on a connector insert that is inserted into the connector receptacle; and
a drive mechanism coupled to the first detector to eject the connector insert from the passage in response to detecting the extraction force on the connector insert.

16. The connector receptacle of claim 15 wherein detecting an extraction force on the connector insert comprises detecting force on the connector insert in an extraction direction, where the force is above a threshold.

17. The connector receptacle of claim 15 wherein the drive mechanism comprises a first roller in a first opening in the passage and a second roller in a second opening in the passage, where the first roller and the second roller include a conductive foam surface.

18. The connector receptacle of claim 15 wherein the front opening has a flanged shape.

19. The connector receptacle of claim 15 further comprising a second detector to detect a presence of the connector insert and in response to detecting the connector insert, the drive mechanism pulls the connector insert into the passage.

20. The connector receptacle of claim 15 further comprising an electromagnet in the passage, where current is provided in a first direction through the electromagnet to pull the connector insert into the connector receptacle and current is provided in a second direction through the electromagnet to eject the connector insert from the connector receptacle.
